(19) United States
(12) Patent Application Publication
(10) Pub. No.: US 2023/0244020 A1
(43) Pub. Date: Aug. 3, 2023

(54) MULTILAYER STRUCTURE AND METHOD OF MANUFACTURING THE SAME

(71) Applicant: NITTO DENKO CORPORATION, Ibaraki-shi, Osaka (JP)

(72) Inventors: Takanobu YANO, Ibaraki-shi, Osaka (JP); Shou TAKARADA, Ibaraki-shi, Osaka (JP); Takeshi NAKANO, Ibaraki-shi, Osaka (JP); Koji SHITARA, Ibaraki-shi, Osaka (JP); Yoshitaka SUGITA, Ibaraki-shi, Osaka (JP); Kazutaka MINOURA, Ibaraki-shi, Osaka (JP)

(21) Appl. No.: 17/766,453

(22) PCT Filed: Oct. 5, 2020
(86) PCT No.: PCT/JP2020/037760

§ 371 Date: Apr. 4, 2022

(30) Foreign Application Priority Data
Oct. 4, 2019 (JP) 2019-183987

(51) Int. Cl. G02B 5/30; H10K 59/40; G02B 1/14; H10K 59/80

(52) U.S. Cl. CPC G02B 5/305; H10K 59/40; G02B 1/14; G02B 5/3083; H10K 59/8793; H10K 59/873

(57) ABSTRACT

The multilayer structure used to be deformed by bending with a first member outside, includes the first member, a first adhesive layer, a second member having one surface joined to one surface of the first member at least via the first adhesive layer, a second adhesive layer, and a first structure having one surface joined to the other surface of the second member at least via the second adhesive layer. The first structure includes a third member on a surface in contact with the second adhesive layer, including, on a surface in contact with the second adhesive layer, a layer that is likely to be broken when deformed. Hardness of each of the first and second adhesive layer is determined such that when the multilayer structure is deformed, the extension of the layer likely to be broken is reduced to a value lower than the tensile breaking extension thereof.

### FIELD OF THE INVENTION

The present invention relates to a multilayer structure used to be deformed by bending.

### BACKGROUND OF THE INVENTION

As disclosed in, for example, Japanese Patent Laid-Open No. 2014-157745, an organic EL display device integrated with a touch sensor has been conventionally known. As shown in FIG. 1, in the organic EL display device in Japanese Patent Laid-Open No. 2014-157745, an optical laminate 920 is provided on a visible side of an organic EL display panel 901, and a touch panel 930 is provided on the visible side of the optical laminate 920. The optical laminate 920 includes a polarizer 921 with opposite surfaces to which protective films 922-1, 922-2 are joined, and a retardation film 923, and the polarizer 921 is provided on the visible side of the retardation film 923. The touch panel 930 has a structure in which transparent conductive films 916-1, 916-2 are arranged with a spacer 917 therebetween, the transparent conductive films 916-1, 916-2 having structures in which substrate films 915-1, 915-2 and transparent conductive layers 912-1, 912-2 are laminated.

Recently a foldable organic EL display device with higher portability has been expected to be achieved.

### CITATION LIST

### Patent Literature

[Patent document 1]
Japanese Patent Laid-Open No. 2014-157745

### SUMMARY OF INVENTION

### Problem to be Solved by the Invention

However, the conventional organic EL display device as disclosed in, for example, Patent document 1 is not designed to be folded. An organic EL display panel substrate formed of a plastic film may provide bendability to an organic EL display panel. However, when the conventional organic EL display device is folded, layers vulnerable to bending such as a transparent conductive layer included in a touch sensor member, a thin film encapsulation layer of the organic EL display panel, and a hard coat layer provided on a surface of a window member, which constitute the organic EL display device, are broken.

Thus, the present invention has an object to achieve a multilayer structure that may suppress break of a layer or member vulnerable to bending when the multilayer structure is folded.

### Means for Solving Problem

One aspect of the present invention provides a multilayer structure including: a first member; a first adhesive layer; a second member having one surface joined to one surface of the first member at least via the first adhesive layer; a second adhesive layer; and a first structure having one surface joined to the other surface of the second member at least via the second adhesive layer, the multilayer structure being used to be deformed by bending with the first member outside, wherein the first structure includes a third member on a surface in contact with the second adhesive layer, the multilayer structure is configured such that when the multilayer structure is deformed by bending, tensile stress acts on at least each of outer surfaces of the first member, the second member, and the third member, in the multilayer structure, the third member of the first structure includes, on a surface in contact with the second adhesive layer, a layer that has tensile breaking extension lower than that of each of the first member and the second member and is likely to be broken when deformed by bending, and hardness of each of the first adhesive layer and the second adhesive layer is determined such that when the multilayer structure is deformed by bending, deformation by bending of the one surface of the first member, deformation by bending of the one surface of the second member, deformation by bending of the other surface of the second member, and deformation by bending of the one surface of the third member interact with one another via the first adhesive layer and the second adhesive layer, and that extension of the layer that is likely to be broken when deformed by bending is reduced to a value lower than the tensile breaking extension of the layer that is likely to be broken.

The hardness of each of the first adhesive layer and the second adhesive layer may be determined by a thickness and/or a shear modulus of each of the first adhesive layer and the second adhesive layer.

The first member may be a window member of a display device, the second member may be a circularly polarizing function film laminate, the third member may be a touch sensor member including a transparent conductive layer formed on a surface closer to the second adhesive layer, and a second structure may be joined to a surface of the touch sensor member opposite to the second adhesive layer via a third adhesive layer.

The second structure may include a panel member, and the panel member may include a thin film encapsulation layer on a surface closer to the third adhesive layer.

The window member may have a hard coat layer on a surface opposite to the first adhesive layer.

The circularly polarizing function film laminate may be a laminate of a polarizing film and a retardation film, and the polarizing film may be a laminate of a polarizer and a polarizer protective film laminated on at least one surface of the polarizer.

The polarizer protective film may contain acrylic resin.

A shear modulus of the second adhesive layer may be higher than a shear modulus of the first adhesive layer.

The second structure may include a fourth adhesive layer on a surface of the panel member opposite to the third adhesive layer, and a protective member laminated via the fourth adhesive layer.

A shear modulus of the fourth adhesive layer may be lower than the shear modulus of the second adhesive layer and lower than a shear modulus of the third adhesive layer.

One aspect of the present invention provides a method of manufacturing a multilayer structure including a first member, a second member having one surface joined to one surface of the first member at least via a first adhesive layer, and a first structure having one surface joined to the other surface of the second member at least via a second adhesive layer, the multilayer structure being used to be deformed by bending with the first member outside, wherein the first structure includes a third member on a surface in contact with the second adhesive layer, the multilayer structure is configured such that when the multilayer structure is deformed by bending, tensile stress acts on at least each of outer surfaces of the first member, the second member, and the third member, in the multilayer structure, the third member of the first structure includes, on a surface in contact with the second adhesive layer, a layer that has tensile breaking extension lower than that of each of the first member and the second member and is likely to be broken when deformed by bending, and the method includes: determining whether the layer that is likely to be broken of the third member has been or is to be broken when deformed by bending, and when it is determined that the layer that is likely to be broken of the third member has been or is to be broken, increasing hardness of at least one of the first adhesive layer and the second adhesive layer, thereby manufacturing the multilayer structure such that extension of the layer that is likely to be broken of the third member when deformed by bending is reduced to a value lower than the tensile breaking extension of the layer that is likely to be broken.

Increasing the hardness of at least one of the first adhesive layer and the second adhesive layer may be increasing a shear modulus of at least one of the first adhesive layer and the second adhesive layer and/or reducing a thickness of at least one of the first adhesive layer and the second adhesive layer.

A second structure may be joined to a surface of the third member opposite to the second adhesive layer via a third adhesive layer, and the method includes determining whether the layer that is likely to be broken of the third member has been or is to be broken when deformed by bending, and when it is determined that the layer that is likely to be broken of the third member has been or is to be broken, reducing hardness of the third adhesive layer, thereby manufacturing the multilayer structure such that extension of the layer that is likely to be broken of the third member when deformed by bending is reduced to a value lower than the tensile breaking extension of the layer that is likely to be broken.

Reducing the hardness of the third adhesive layer may be reducing a shear modulus of the third adhesive layer and/or increasing a thickness of the third adhesive layer.

The third member may be a touch sensor member, the layer that is likely to be broken may be a transparent conductive layer formed on a surface of the touch sensor member closer to the second adhesive layer, the second structure may include a panel member, the panel member may include a thin film encapsulation layer on a surface closer to the third adhesive layer, the second structure may further include a fourth adhesive layer on a surface of the panel member opposite to the third adhesive layer, and a protective member laminated via the fourth adhesive layer, and the method may include determining whether the transparent conductive layer has been or is to be broken when deformed by bending, and when it is determined that the transparent conductive layer has been or is to be broken, reducing hardness of at least one of the third adhesive layer and the fourth adhesive layer, thereby manufacturing the multilayer structure such that extension of the transparent conductive layer when deformed by bending is reduced to a value lower than the tensile breaking extension of the transparent conductive layer.

Reducing the hardness of at least one of the third adhesive layer and the fourth adhesive layer may be reducing a shear modulus of at least one of the third adhesive layer and the fourth adhesive layer and/or increasing a thickness of at least one of the third adhesive layer and the fourth adhesive layer.

### Effect of the Invention

According to the present invention, a foldable multilayer structure may be achieved that may suppress break of a layer or member vulnerable to bending when the multilayer structure is folded.

Now, with reference to the drawings, embodiments of a multilayer structure according to the present invention will be described in detail.

### BRIEF DESCRIPTION OF THE DRAWINGS

FIG. 1 is a sectional view of a conventional organic EL display device;

FIG. 2 is a sectional view of a multilayer structure according to one embodiment of the present invention;

FIG. 3 is a sectional view of a multilayer structure according to another embodiment of the present invention;

FIG. 4 shows a method of manufacturing a retardation film used in one embodiment;

FIG. 5 shows a simulation method according to an embodiment of the present invention;

FIG. 6 illustrates strain perpendicular to a bending radius direction;

FIG. 7 shows strain distributions in a laminating direction of examples and a comparative example with varying shear modulus G′ of a second adhesive layer;

FIG. 8 shows strain distributions in a laminating direction of examples with varying shear modulus G′ of a third adhesive layer;

FIG. 9 shows strain distributions in a laminating direction of examples with varying shear modulus G′ of a fourth adhesive layer;

FIG. 10 shows strain distributions in a laminating direction of examples with varying shear modulus G′ of a first adhesive layer;

FIG. 11 shows a relationship between A/A′ and B/B′; and

FIG. 12 shows a method of evaluating cracking.

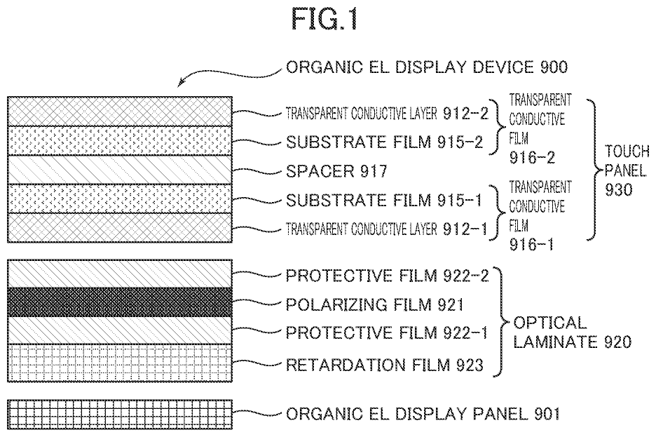

### DESCRIPTION OF EMBODIMENTS

### [Second Member]

A second member used in a multilayer structure according to the present invention may be a film such as a polarizer, a polarizing film, a protective film made of a transparent resin material, or a retardation film, a combination of some or all of them, in particular, a circularly polarizing function film laminate including the retardation film laminated on the polarizing film. The second member does not include an adhesive layer such as a first adhesive layer described later. The second member has one surface joined to one surface of a first member at least via the first adhesive layer.

The second member preferably has a thickness of 92 μm or less, more preferably has a thickness of 60 μm, and further preferably has a thickness of 10 to 50 μm. The thickness within the range does not hinder bending and is preferable.

### <Polarizer>

The polarizer included in the second member in the present invention may be iodine-oriented polyvinyl alcohol (PVA) resin stretched by a stretching step such as stretching in air (dry stretching) or stretching in a boric acid solution.

An example of a method of manufacturing a polarizer typically includes a method including steps of dyeing and stretching a single layer of PVA resin (single-layer stretching) as disclosed in Japanese Patent Laid-Open No. 2004-341515. Another example of such a method includes a method including steps of stretching and dyeing a laminate of a PVA resin layer and a stretching resin substrate as disclosed in Japanese Patent Laid-Open No. 51-069644, Japanese Patent Laid-Open No. 2000-338329, Japanese Patent Laid-Open No. 2001-343521, International Publication No. WO2010/100917, Japanese Patent Laid-Open No. 2012-073563, and Japanese Patent Laid-Open No. 2011-2816. Such a method allows stretching of even a thin PVA resin layer without any trouble such as break due to stretching because the PVA resin layer is supported by the stretching resin substrate.

The polarizer has a thickness of 20 μm or less, preferably has a thickness of 12 μm or less, more preferably has a thickness of 9 μm or less, further preferably has a thickness of 1 to 8 μm, and particularly preferably 3 to 6 μm. The thickness within the range does not hinder bending and is preferable.

### <Polarizing Film>

The polarizer may have a polarizer protective film bonded to at least one side thereof by an adhesive (layer) (not shown) as long as the feature of the present invention is not impaired. The polarizer and the polarizer protective film may be bonded by an adhesive. Examples of the adhesive include an isocyanate adhesive, a polyvinyl alcohol adhesive, a gelatin adhesive, vinyl latex, water-based polyester, and the like. The adhesive is generally used as an aqueous solution of the adhesive having a solid content of 0.5% to 60% by weight. Other examples of the adhesive between the polarizer and the polarizer protective film include an ultraviolet curable adhesive, an electron beam curable adhesive, and the like. The electron beam curable adhesive for polarizing film exhibits appropriate adhesiveness to the various polarizer protective films described above. The adhesive used in the present invention may contain a metal compound filler. In the present invention, the polarizer and the polarizer protective film bonded by the adhesive (layer) is sometimes referred to as a polarizing film.

### <Retardation Film>

The optical film member used in the present invention may include a retardation film, and the retardation film may be obtained by stretching a polymer film or orienting and solidifying a liquid crystal material. The retardation film herein refers to a film having birefringence in an in-plane and/or thickness direction.

Examples of the retardation film include an antireflection retardation film (see [0221], [0222], and [0228] in Japanese Patent Laid-Open No. 2012-133303), a viewing angle compensating retardation film (see [0225] and [0226] in Japanese Patent Laid-Open No. 2012-133303), a viewing angle compensating obliquely oriented retardation film ([0227] in Japanese Patent Laid-Open No. 2012-133303), and the like.

Any known retardation film may be used as long as it substantially has the function described above, without any limitation of, for example, a retardation value, an arrangement angle, a three-dimensional birefringence index, and whether the film is a single layer or a multilayer.

The retardation film preferably has a thickness of 20 μm or less, more preferably has a thickness of 10 μm or less, further preferably has a thickness of 1 to 9 μm, and particularly preferably has a thickness of 3 to 8 μm. The thickness within the range does not hinder bending and is preferable.

Re[550] herein refers to an in-plane retardation value measured at 23° C. using light having a wavelength of 550 nm. Re[550] may be calculated by an expression: Re[550]=(nx−ny)×d, where nx and ny are refractive indexes at a wavelength of 550 nm in a slow axis direction and a fast axis direction of the retardation film, and d (nm) is a thickness of the retardation film. The slow axis direction refers to a direction with a maximum in-plane refractive index.

In-plane birefringence Δn equal to nx−ny in the present invention is 0.002 to 0.2, and preferably 0.0025 to 0.15.

The retardation film preferably has an in-plane retardation value (Re[550]) measured at 23° C. using light having a wavelength of 550 nm, which is larger than an in-plane retardation value (Re[450]) measured using light having a wavelength of 450 nm. If the ratio falls within the range, the retardation film having such a wavelength dispersion property may cause larger retardation at a longer wavelength, so that an ideal retardation property may be obtained at each wavelength in a visible region. For example, when used in an organic EL display, a retardation film having such wavelength dependence may be produced as a quarter wave plate and bonded to a polarizing plate to produce a circularly polarizing plate or the like. This can achieve a neutral polarizing plate and a display device having low dependence of hue on wavelength. On the other hand, if the ratio does not fall within the range, dependence of hue of reflected light on wavelength increases, causing a coloring problem in the polarizing plate and the display device.

The ratio (Re[450]/Re[550]) of Re[550] to Re[450] of the retardation film is 0.8 to less than 1.0, and more preferably 0.8 to 0.95.

The retardation film preferably has an in-plane retardation value (Re[550]) measured at 23° C. using light having a wavelength of 550 nm, which is lower than an in-plane retardation value (Re[650]) measured using light having a wavelength of 650 nm. The retardation film having such a wavelength dispersion property has a constant retardation value in a red region. Thus, when used in, for example, a liquid crystal display device, the retardation film may improve a phenomenon that light leakage occurs when viewed from different angles or a phenomenon that a display image becomes reddish (also referred to as “reddish phenomenon”).

A ratio (Re[550]/Re[650]) of Re[650] to Re[550] of the retardation film is 0.8 to less than 1.0, and preferably 0.8 to 0.97. The ratio Re[550]/Re[650] within the above range may provide a more excellent display property when the retardation film is used, for example, in an organic EL display.

Re[450], Re[550], and Re[650] may be measured using “AxoScan” (product name) manufactured by Axometrics, Inc.

In one embodiment, the retardation film in the present invention is produced by stretching and orienting a polymer film.

As a method of stretching the polymer film, any suitable stretching method may be used depending on the purpose. Examples of the stretching method suitable for the present invention include a transverse uniaxial stretching method, a longitudinal and transverse simultaneous biaxial stretching method, a longitudinal and transverse sequential biaxial stretching method, and the like. As a stretching device, any suitable stretching machine such as a tenter stretching machine or a biaxial stretching machine may be used. Preferably, the stretching machine includes a temperature controller. When stretching is performed under heating, an internal temperature of the stretching machine may be changed continuously or changed in steps. A stretching step may be a single step or may be divided into two or more steps. A stretching direction is preferably a film width direction (TD direction) or an oblique direction.

In another embodiment, the retardation film in the present invention may include a laminate of retardation layers produced by orienting and solidifying a liquid crystal material. Each retardation layer may be an oriented and solidified layer of a liquid crystal compound. Using the liquid crystal compound may significantly increase a difference between nx and ny of each retardation layer obtained as compared to using a non-liquid crystal material, thereby significantly reducing a thickness of each retardation layer for obtaining desired in-plane retardation. This may further reduce a thickness of a circularly polarizing plate (finally an organic EL display device). The term “oriented and solidified layer” herein refers to a layer in which a liquid crystal compound is oriented in a predetermined direction and an orientation state is fixed. In this embodiment, typically a rod-like liquid crystal compound is oriented in a slow axis direction of the retardation layer (homogeneous orientation). An example of the liquid crystal compound includes, for example, a liquid crystal compound (nematic liquid crystal) having a nematic liquid crystal phase. Examples of the liquid crystal compound include a liquid crystal polymer and a liquid crystal monomer. A mechanism of expressing liquid crystallinity of the liquid crystal compound may be lyotropic or thermotropic. The liquid crystal polymer and the liquid crystal monomer may be used alone or in combination.

When the liquid crystal compound is the liquid crystal monomer, the liquid crystal monomer is preferably a polymerizable monomer and a cross-linkable monomer. This is because the orientation state of the liquid crystal monomer may be fixed by polymerization or crosslinking of the liquid crystal monomer. After liquid crystal monomers are oriented, for example, the liquid crystal monomers may be polymerized or crosslinked to one another to fix the orientation state. A polymer is formed by polymerization, and a three-dimensional network is formed by crosslinking, and these are non-liquid crystalline. Thus, the retardation layer formed does not undergo, for example, transition to a liquid crystal phase, a glass phase, or a crystal phase caused by temperature change peculiar to the liquid crystal compound. As a result, the retardation layer is not affected by the temperature change and is very stable.

A temperature range in which the liquid crystal monomer exhibits liquid crystallinity depends on the type thereof. Specifically, the temperature range is preferably 40° C. to 120° C., more preferably 50° C. to 100° C., and further preferably 60° C. to 90° C.

Any suitable liquid crystal monomer may be used as the liquid crystal monomer. Examples thereof include polymerizable mesogenic compounds and the like disclosed, for example, in Japanese Translation of PCT International Application Publication No. 2002-533742 (WO00/37585), EP358208 (U.S. Pat. No. 5,211,877), EP66137 (U.S. Pat. No. 4,388,453), WO93/22397, EP0261712, DE19504224, DE4408171, and GB2280445. Specific examples of such polymerizable mesogenic compounds include LC242 (trade name) manufactured by BASF SE, E7 (trade name) manufactured by Merck KGaA, and LC-Sillicon-CC3767 (trade name) manufactured by Wacker-Chemie AG. As the liquid crystal monomer, for example, a nematic liquid crystal monomer is preferable.

The oriented and solidified layer of the liquid crystal compound may be formed by orienting a surface of a predetermined substrate, applying a coating solution containing the liquid crystal compound to the surface to orient the liquid crystal compound in a direction of the above orientation, and fixing the orientation state. In one embodiment, the substrate may be any suitable resin film, and the oriented and solidified layer formed on the substrate may be transferred to a surface of a polarizer. In this case, the oriented and solidified layer is arranged such that an angle formed between an absorption axis of the polarizer and a slow axis of the liquid crystal oriented and solidified layer is 15°. A retardation of the liquid crystal oriented and solidified layer is λ/2 (about 270 nm) with respect to the wavelength of 550 nm. Further, a liquid crystal oriented and solidified layer with a retardation of λ/4 (about 140 nm) with respect to the wavelength of 550 nm as described above is formed on the substrate to which the liquid crystal oriented and solidified layer may be transferred, and laminated on a side of a half wave plate of a laminate including the polarizer and the half wave plate such that an angle formed between the absorption axis of the polarizer and a slow axis of a quarter wave plate is 75°.

### <Polarizer Protective Film>

A polarizer protective film used in the multilayer structure according to the present invention may be made of a transparent resin material, for example, cycloolefin resin such as norbornene resin, olefin resin such as polyethylene or polypropylene, polyester resin, or (meth)acrylic resin.

The polarizer protective film preferably has a thickness of 5 to 60 μm, more preferably has a thickness of 10 to 40 μm, further preferably has a thickness of 10 to 30 μm, and may include a surface-treated layer such as an anti-glare layer or an antireflection layer as appropriate. The thickness within the range does not hinder bending and is preferable.

Moisture permeability of the polarizer protective film used in the optical laminate in the present invention is 200 g/m² or less, preferably 170 g/m² or less, more preferably 130 g/m² or less, and particularly preferably 90 g/m² or less.

### [First Member]

The first member in the present invention may be a window member of a display device.

### [Window Member]

The window member is arranged on an outermost surface on a visible side of the multilayer structure to prevent damage to the circularly polarizing function film laminate, a touch sensor member, and a panel member.

The window member generally includes a window film or a window glass. The window film or the window glass may include a hard coat layer. An example of the window glass includes a thin glass substrate. An optical laminate applied to a foldable multilayer structure device requires high flexibility high transparency and high hardness. The window film may be made of any material that satisfies these physical properties.

### <Window Film>

An example of the window film includes a transparent resin film. Examples of resin for forming the transparent resin film include at least one of resins selected from polyimide resin, polyamide resin, polyester resin, cellulose resin, acetate resin, styrene resin, sulfone resin, epoxy resin, polyolefin resin, polyetheretherketone resin, sulfide resin, vinyl alcohol resin, urethane resin, acrylic resin, and polycarbonate resin. However, the resin for forming the transparent resin film is not limited thereto.

### <Hard Coat Layer>

A hard coat layer is formed by applying a curable coating agent to a surface of a layer as a base (for example, the window film) and curing the coating agent.

A coating agent, for example, for an optical film may be used. Examples of the coating agent include, but not limited to, an acrylic coating agent, a melamine coating agent, a urethane coating agent, an epoxy coating agent, a silicone coating agent, and an inorganic coating agent.

The coating agent may contain additives. Examples of the additives include, but not limited to, a silane coupling agent, a coloring agent, a dye, powder or particles (pigment, inorganic or organic filler, particles of inorganic or organic material), a surfactant, a plasticizer, an antistatic agent, a surface lubricant, a leveling agent, an antioxidant, a light stabilizer, an ultraviolet absorber, a polymerization inhibitor, an antifoulant, and the like.

[First Adhesive Layer]A first adhesive layer used in the multilayer structure according to the present invention is provided such that the window member is laminated on one surface of the optical film member via the first adhesive layer.

Examples of an adhesive composition for forming the first adhesive layer used in the multilayer structure according to the present invention include an acrylic adhesive, a rubber adhesive, a vinyl alkyl ether adhesive, a silicone adhesive, a polyester adhesive, a polyamide adhesive, a urethane adhesive, a fluorine adhesive, an epoxy adhesive, a polyether adhesive, and the like. Such an adhesive for forming the first adhesive layer may be used alone, or two or more adhesives may be used in combination. However, the acrylic adhesive is preferably used alone in terms of transparency workability durability adhesiveness, resistance to bending, and the like.

### <(Meth)Acrylic Polymer>

When the acrylic adhesive is used as the adhesive composition for forming the first adhesive layer, the acrylic adhesive preferably contains a (meth)acrylic polymer containing, as a monomer unit, a (meth)acrylic monomer containing linear or branched alkyl groups having 1 to 24 carbon atoms. Using the (meth)acrylic monomer containing linear or branched alkyl groups having 1 to 24 carbon atoms may provide an adhesive layer with high bendability. The (meth)acrylic polymer in the present invention refers to an acrylic polymer and/or a methacrylic polymer, and (meth)acrylate refers to acrylate and/or methacrylate.

Specific examples of the (meth)acrylic monomer containing linear or branched alkyl groups having 1 to 24 carbon atoms, which forms a main skeleton of the (meth)acrylic polymer, include methyl (meth)acrylate, ethyl (meth)acrylate, n-butyl (meth)acrylate, s-butyl (meth)acrylate, t-butyl (meth)acrylate, isobutyl (meth)acrylate, n-pentyl (meth)acrylate, isopentyl (meth)acrylate, n-hexyl (meth)acrylate, isohexyl (meth)acrylate, isoheptyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate, n-tridecyl (meth)acrylate, n-tetradecyl (meth)acrylate, and the like. Among them, a (meth)acrylic monomer containing linear or branched alkyl groups having 4 to 8 carbon atoms is preferable in terms of bendability because a monomer with a low glass transition temperature (Tg) is generally viscoelastic even in a high speed region in bending. One (meth)acrylic monomer or two or more (meth)acrylic monomers may be used.

The (meth)acrylic monomer containing linear or branched alkyl groups having 1 to 24 carbon atoms is a main component of all the monomers that form the (meth)acrylic polymer. As the main component, the (meth)acrylic monomer containing linear or branched alkyl groups having 1 to 24 carbon atoms is preferably 80% to 100% by weight, more preferably 90% to 100% by weight, further preferably 92% to 99.9% by weight, and particularly preferably 94% to 99.9% by weight of all the monomers that form the (meth)acrylic polymer.

When the acrylic adhesive is used as the adhesive composition for forming the first adhesive layer, the acrylic adhesive preferably contains a (meth)acrylic polymer containing, as a monomer unit, a hydroxyl group-containing monomer having a reactive functional group. Using the hydroxyl group-containing monomer may provide an adhesive layer with high adhesiveness and bendability. The hydroxyl group-containing monomer is a compound containing a hydroxyl group in its structure and including a polymerizable unsaturated double bond of a (meth)acryloyl group, a vinyl group, or the like.

Specific examples of the hydroxyl group-containing monomer include hydroxyalkyl (meth)acrylate such as 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate, (4-hydroxymethyl cyclohexyl)-methylacrylate, and the like. Among the hydroxyl group-containing monomers, 2-hydroxyethyl (meth)acrylate and 4-hydroxybutyl (meth)acrylate are preferable in terms of durability and adhesiveness. One hydroxyl group-containing monomer or two or more hydroxyl group-containing monomers may be used.

The acrylic adhesive may contain, as monomer units that form the (meth)acrylic polymer, monomers such as a carboxyl group-containing monomer, an amino group-containing monomer, an amide group-containing monomer, and the like, which have reactive functional groups. Using such monomers is preferable in terms of adhesiveness under moist heat environment.

When the acrylic adhesive is used as the adhesive composition for forming the first adhesive layer, the acrylic adhesive may contain a (meth)acrylic polymer containing, as a monomer unit, a carboxyl group-containing monomer having a reactive functional group. Using the carboxyl group-containing monomer may provide an adhesive layer with high adhesiveness under moist heat environment. The carboxyl group-containing monomer is a compound containing a carboxyl group in its structure and including a polymerizable unsaturated double bond of a (meth) acryloyl group, a vinyl group, or the like.

Specific examples of the carboxyl group-containing monomer include (meth)acrylic acid, carboxyethyl (meth)acrylate, carboxypentyl (meth)acrylate, itaconic acid, maleic acid, fumaric acid, and crotonic acid, and the like.

When the acrylic adhesive is used as the adhesive composition for forming the first adhesive layer, the acrylic adhesive may contain a (meth)acrylic polymer containing, as a monomer unit, an amino group-containing monomer having a reactive functional group. Using the amino group-containing monomer may provide an adhesive layer with high adhesiveness under moist heat environment. The amino group-containing monomer is a compound containing an amino group in its structure and including a polymerizable unsaturated double bond of a (meth) acryloyl group, a vinyl group, or the like.

Specific examples of the amino group-containing monomer include N,N-dimethylaminoethyl (meth)acrylate, N,N-dimethylaminopropyl (meth)acrylate, and the like.

When the acrylic adhesive is used as the adhesive composition for forming the first adhesive layer, the acrylic adhesive may contain a (meth)acrylic polymer containing, as a monomer unit, an amide group-containing monomer having a reactive functional group. Using the amide group-containing monomer may provide an adhesive layer with high adhesiveness. The amide group-containing monomer is a compound containing an amide group in its structure and including a polymerizable unsaturated double bond of a (meth) acryloyl group, a vinyl group, or the like.

Specific examples of the amide group-containing monomer include acrylamide monomers such as (meth)acrylamide, N,N-dimethyl (meth)acrylamide, N,N-diethyl (meth)acrylamide, N-isopropyl acrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloyl morpholine, N-(meth)acryloyl piperidine, and N-(meth)acryloyl pyrrolidine; N-vinyl group-containing lactam monomers such as N-vinyl pyrrolidone, N-vinyl-ε-caprolactam, and the like.

As the monomer unit that forms the (meth)acrylic polymer, the content (total amount) of the monomer having the reactive functional group is preferably 20% by weight or less, more preferably 10% by weight or less, further preferably 0.01% to 8% by weight, particularly preferably 0.01% to 5% by weight, and most preferably 0.05% to 3% by weight of all the monomers that form the (meth)acrylic polymer. The content of more than 20% by weight increases the number of crosslinking points, which may reduce flexibility of an adhesive (layer) and reduce stress relaxation properties.

As the monomer units that form the (meth)acrylic polymer, besides the monomers having the reactive functional groups, other copolymerizable monomers may be introduced without impairing the advantage of the present invention. The content of the copolymerizable monomer is not particularly limited, but is preferably 30% by weight or less of all the monomers that form the (meth)acrylic polymer, and more preferably no copolymerizable monomer is contained. In particular, when a monomer other than the (meth)acrylic monomer is used, the content of more than 30% by weight reduces the number of points of reaction with a film, which may reduce adhesiveness.

When the (meth)acrylic polymer is used in the present invention, a weight average molecular weight (Mw) of the (meth)acrylic polymer is generally 1,000,000 to 2,500,000. The weight average molecular weight is preferably 1,200,000 to 2,200,000, and more preferably 1,400,000 to 2,000,000 in terms of durability particularly heat resistance and bendability. The weight average molecular weight of less than 1,000,000 increases the number of crosslinking points and reduces flexibility of an adhesive (layer) as compared to the weight average molecular weight of 1,000,000 or more when polymer chains are crosslinked to ensure durability. Thus, dimensional changes in a bent outer side (protruding side) and a bent inner side (recessed side) that occur in each film in bending cannot be reduced, which is likely to cause break of a film. The weight average molecular weight of more than 2,500,000 is not preferable because a large amount of diluting solvent is required to adjust to viscosity for coating, which increases cost. Also, polymer chains of the (meth)acrylic polymer obtained are entangled in a complicated manner, thereby reducing flexibility which is likely to cause break of a film. The weight average molecular weight (Mw) is a value measured by gel permeation chromatography (GPC) and calculated as polystyrene.

Such a (meth)acrylic polymer may be manufactured by any known manufacturing method such as solution polymerization, bulk polymerization, emulsion polymerization, and various radical polymerizations. The (meth)acrylic polymer obtained may be any of a random copolymer, a block copolymer, a graft copolymer, and the like.

In the solution polymerization, for example, acetic ethyl, toluene, or the like is used as a polymerization solvent. As a specific example, the solution polymerization is performed by adding a polymerization initiator in a flow of an inactive gas such as nitrogen, generally under a reaction condition at about 50° C. to 70° C. for about 5 to 30 hours.

A polymerization initiator, a chain transfer agent, an emulsifier, and the like used in the radical polymerization are not particularly limited, but may be selected as appropriate. The weight average molecular weight of the (meth)acrylic polymer may be controlled depending on usage of the polymerization initiator or the chain transfer agent, and the reaction condition, and the usage is adjusted depending on type of the polymerization initiator or the chain transfer agent.

Examples of the polymerization initiator may include, but not limited to, azo initiators such as 2,2′-azobisisobutyronitrile, 2,2′-azobis (2-amidinopropane) dihydrochloride, 2,2′-azobis[2-(5-methyl-2-imidazoline-2-il)propane]dihydrochloride, 2,2′-azobis(2-methylpropioneamidine)disulfate, 2,2′-azobis(N,N′-dimethyleneisobutyl amidine), and 2,2′-azobis[N-(2-carboxyethyl)-2-methylpropioneamidine] hydrate (trade name: VA-057, manufactured by Wako Pure Chemical Corporation); peroxide initiators such as persulfate such as potassium persulfate and ammonium persulfate, di(2-ethyl hexyl)peroxydicarbonate, di(4-t-butyl cyclohexyl)peroxydicarbonate, di-sec-butyl peroxydicarbonate, t-butyl peroxyneodecanoate, t-hexyl peroxypivalate, t-butyl peroxypivalate, dilauroylperoxide, di-n-octanoylperoxide, 1,1,3,3-tetramethylbutyl peroxy-2-ethyl hexanoate, di(4-methylbenzoyl)peroxide, dibenzoylperoxide, t-butyl peroxyisobutyrate, 1,1-di(t-hexyl peroxy)cyclohexane, t-butyl hydroperoxide, and hydrogen peroxide; redox initiators containing a combination of peroxide and a reducing agent such as a combination of persulfate and sodium bisulfite and a combination of peroxide and sodium ascorbate, and the like.

One polymerization initiator or two or more polymerization initiators may be mixed and used, but the overall content of the polymerization initiator is preferably for example, about 0.005 to 1 part by weight, and more preferably about 0.02 to 0.5 parts by weight with respect to 100 parts by weight of all the monomers that form the (meth)acrylic polymer.

When a chain transfer agent, or an emulsifier or a reactive emulsifier for emulsion polymerization is used, any known agent or emulsifier may be used as appropriate. The content thereof may be determined as appropriate without impairing the advantage of the invention.

### <Crosslinker>

The adhesive composition for forming the first adhesive layer may contain a crosslinker. As the crosslinker, an organic crosslinker or polyfunctional metal chelate may be used. Examples of the organic crosslinker include an isocyanate crosslinker, a peroxide crosslinker, an epoxy crosslinker, an imine crosslinker, and the like. The polyfunctional metal chelate is polyvalent metal covalent-bonded or coordinate-bonded to an organic compound. Examples of polyvalent metal atoms include Al, Cr, Zr, Co, Cu, Fe, Ni, V, Zn, In, Ca, Mg, Mn, Y, Ce, Sr, Ba, Mo, La, Sn, Ti, and the like. Examples of atoms in the organic compound to which the polyvalent metal is covalent-bonded or coordinate-bonded include an oxygen atom and the like, and examples of the organic compound include alkyl ester, an alcohol compound, a carboxylic compound, an ether compound, a ketone compound, and the like. Among them, the isocyanate crosslinker (particularly, a trifunctional isocyanate crosslinker) is preferable in terms of durability and the peroxide crosslinker and the isocyanate crosslinker (particularly a bifunctional isocyanate crosslinker) are preferable in terms of bendability. The peroxide crosslinker and the bifunctional isocyanate crosslinker both form flexible two-dimensional crosslinking, while the trifunctional isocyanate crosslinker forms stronger three-dimensional crosslinking. The two-dimensional crosslinking that is more flexible is advantageous in bending. However, since only the two-dimensional crosslinking provides poor durability and is likely to cause peeling, hybrid crosslinking of the two-dimensional crosslinking and the three-dimensional crosslinking is preferable. Thus, the trifunctional isocyanate crosslinker and the peroxide crosslinker or the bifunctional isocyanate crosslinker are preferably used in combination.

The content of the crosslinker is, for example, preferably 0.01 to 10 parts by weight, and more preferably 0.03 to 2 parts by weight with respect to 100 parts by weight of the (meth)acrylic polymer. The content within the range provides high resistance to bending and is preferable.

### <Other Additives>

The adhesive composition for forming the first adhesive layer may further contain other known additives depending on use as appropriate. Examples of the additives include various silane coupling agents, a polyether compound of polyalkylene glycol such as polypropylene glycol, a coloring agent, powder such as pigment, a dye, a surfactant, a plasticizer, a tackifier, a surface lubricant, a leveling agent, a softener, an antioxidant, an age resistor, a light stabilizer, an ultraviolet absorber, a polymerization inhibitor, an antistatic agent (such as alkali metal salt or ion liquid that is an ionic compound), an inorganic or organic filler, metallic powder, particles, foil, and the like. A redox agent with a reducing agent may be used within a controllable range.

### [Other Adhesive Layers]

At least via a second adhesive layer used in the multilayer structure according to the present invention, one surface of a first structure is joined to the other surface of the second member.

Via a third adhesive layer used in the multilayer structure according to the present invention, a second structure is joined to a surface of the touch sensor member opposite to the second adhesive layer.

The second adhesive layer, the third adhesive layer, and further adhesive layers may have the same composition (the same adhesive composition) and the same property or may have different properties.

### <Formation of Adhesive Layer>

The plurality of adhesive layers in the present invention are preferably made of the adhesive composition. An example of a method of forming the adhesive layer may include a method of applying the adhesive composition to a separator or the like having been subjected to a release process, and drying and removing a polymerization solvent or the like to form an adhesive layer. The adhesive layer may be formed by a method of applying the adhesive composition to a polarizing film or the like, and drying and removing a polymerization solvent or the like to form an adhesive layer on the polarizing film or the like. In applying the adhesive composition, one or more solvents other than the polymerization solvent may be newly added as appropriate.

The separator having been subjected to a peeling process is preferably a silicone release liner. When the adhesive composition in the present invention is applied onto such a liner and dried to form an adhesive layer, the adhesive may be dried by any appropriate method depending on the purpose. A method of heating and drying the coating film is preferably used. When an acrylic adhesive containing a (meth)acrylic polymer is prepared, for example, a heating and drying temperature is preferably 40° C. to 200° C., more preferably 50° C. to 180° C., and particularly preferably 70° C. to 170° C. The heating temperature within the range provides an adhesive with high adhesiveness.

The drying time may be any suitable time as appropriate. When an acrylic adhesive containing a (meth)acrylic polymer is prepared, for example, the drying time is preferably 5 seconds to 20 minutes, more preferably 5 seconds to 10 minutes, and particularly preferably 10 seconds to 5 minutes.

Various methods may be used for applying the adhesive composition. Specific examples of the method include roll coating, kiss-roll coating, gravure coating, reverse coating, roll brushing, spray coating, dip roll coating, bar coating, knife coating, air knife coating, curtain coating, lip coating, extrusion coating using a dye coater, and the like.

The adhesive layer used in the multilayer structure according to the present invention preferably has a thickness of 1 to 200 μm, more preferably has a thickness of 5 to 150 μm, and further preferably has a thickness of 10 to 100 μm. The adhesive layer may be a single layer or may include a laminate structure. The thickness within the range does not hinder bending and is preferable also in terms of adhesiveness (retention). When a plurality of adhesive layers are included, all the adhesive layers preferably each have the thickness within the range.

An upper limit value of a glass transition temperature (Tg) of the adhesive layer used in the multilayer structure according to the present invention is preferably 0° C. or less, more preferably −20° C. or less, and further preferably −25° C. or less. With the glass transition temperature (Tg) of the adhesive layer within such a range, the adhesive layer is less likely to be hard even in a high speed region in bending, and a bendable or foldable multilayer structure with high stress relaxation properties may be achieved.

### [First Structure]

The first structure has one surface joined to the other surface of the second member at least via the second adhesive layer, and includes a third member on a surface in contact with the second adhesive layer.

### [Third Member]

When the multilayer structure is deformed by bending, tensile stress acts on the third member. In the multilayer structure, the third member includes, on a surface in contact with the second adhesive layer, a layer that has tensile breaking extension lower than that of each of the first member and the second member and is likely to be broken when deformed by bending. The third member in the present invention may be the touch sensor member including a transparent conductive layer formed on a surface closer to the second adhesive layer.

### [Touch Sensor Member]

A touch sensor member used in the field of, for example, image multilayer structures is used. Examples of the touch sensor member include, but not limited to, a resistive touch sensor member, a capacitive touch sensor member, an optical touch sensor member, and an ultrasonic touch sensor member.

The capacitive touch sensor member generally includes a transparent conductive layer. An example of such a touch sensor member includes a laminate of a transparent conductive layer and a transparent substrate. An example of the transparent substrate includes a transparent film.

### <Transparent Conductive Layer>

As a transparent conductive layer, conductive metal oxide, a metallic nanowire, or the like is used, but not limited thereto. Examples of the metal oxide include indium tin oxide (ITO) containing tin oxide, and tin oxide containing antimony. The transparent conductive layer may be a conductive pattern formed of metal oxide or metal. Examples of the shape of the conductive pattern include, but not limited to, a stripe shape, a square shape, a lattice shape, and the like.

### <Transparent Film>

As a transparent film, for example, a transparent resin film is used. Examples of resins for forming the transparent film include polyester resin (also including polyarylate resin), acetate resin, polyethersulfone resin, polycarbonate resin, polyamide resin, polyimide resin, polyolefin resin, acrylic resin, polyvinyl chloride resin, polyvinylidene chloride resin, polystyrene resin, polyvinyl alcohol resin, sulfide resin (for example, polyphenylene sulfide resin), polyetheretherketone resin, cellulose resin, epoxy resin, urethane resin, and the like. The transparent film may contain one of these resins or two or more resins. Among the resins, polyester resin, polyimide resin, and polyethersulfone resin are preferable. However, the resins for forming the transparent film are not limited thereto.

### [Second Structure]

The second structure is joined to the surface of the touch sensor member opposite to the second adhesive layer via the third adhesive layer. The second structure may include a panel member.

### [Panel Member]

A panel member may include an image display panel, and a panel base such as a substrate that holds the image display panel. An encapsulation member (such as a thin film encapsulation layer) is arranged on a visible side of the image display panel. The substrate may be able to hold the image display panel and have appropriate strength and flexibility. A resin sheet or the like is used as the substrate. A material of the resin sheet is not particularly limited, but may be selected depending on the type of the panel.

Any known image display panel is used. An example of the image display panel includes an organic electro luminescence (EL) panel. The image display panel is not limited to the organic EL panel, but may be a liquid crystal panel, an electrophoretic display panel (electronic paper), or the like. For example, flexible substrates such as resin substrates may be used as transparent substrates to sandwich a liquid crystal layer therebetween to form a foldable liquid crystal panel.

### <Thin Film Encapsulation Layer>

A thin film encapsulation layer (TFE) has a function of preventing the image display panel from being exposed to moisture and/or air. The thin film encapsulation layer is formed of an inorganic and organic multilayer film including passivation films and resin films alternately laminated on a light emission layer. Examples of materials for the thin film encapsulation layer include materials with low moisture permeability for example, inorganic materials such as silicon nitride, silicon oxynitride, carbon oxide, carbon nitride, and aluminum oxide, and resin.

### [Protective Member]

A protective member is laminated on an opposite surface of the panel member to the third adhesive layer via the fourth adhesive layer. The protective member serves as a reinforcing plate that is attached to a back surface of the flexible image display panel and reinforces mechanical strength. Also, the protective member is a resin substrate for protecting the flexible image display panel from damage or impact, and is in the form of a film.

### [Multilayer Structure]

The multilayer structure according to the present invention includes a first member, a first adhesive layer, a second member having one surface joined to one surface of the first member at least via the first adhesive layer, a second adhesive layer, and a first structure having one surface joined to the other surface of the second member at least via the second adhesive layer, and the multilayer structure is used to be deformed by bending with the first member outside. The multilayer structure is configured such that when the multilayer structure is deformed by bending, tensile stress acts on each of the first member, the second member, and the third member.

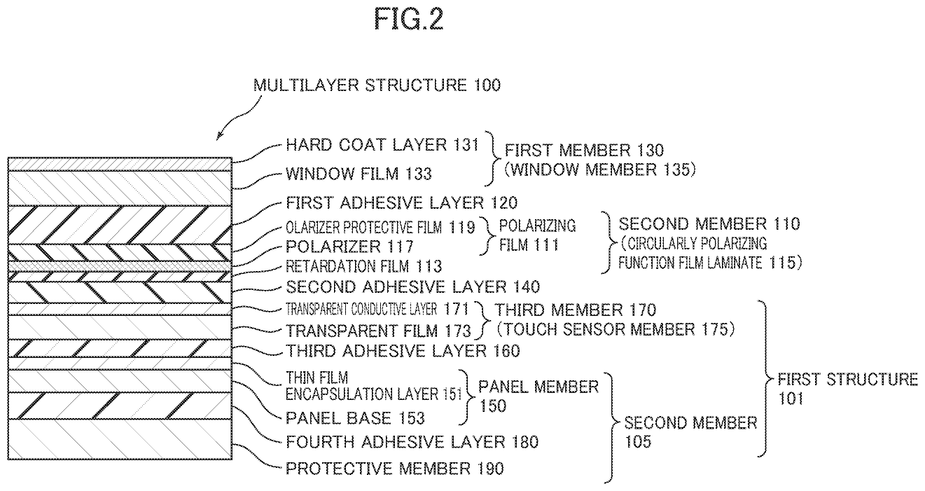

FIG. 2 is a sectional view of one embodiment of the multilayer structure according to the present invention. The multilayer structure 100 includes a first member 130, a first adhesive layer 120, a second member 110 (circularly polarizing function film laminate 115) having one surface joined to one surface of the first member 130 via the first adhesive layer 120, a second adhesive layer 140, and a first structure 101 having one surface joined to the other surface of the second member 110 (circularly polarizing function film laminate 115) via the second adhesive layer 140. The first structure 101 has one surface joined to the other surface of the second member 110 (circularly polarizing function film laminate 115) via the second adhesive layer 140, and includes a third member 170 on a surface in contact with the second adhesive layer 140. The multilayer structure 100 is used to be deformed by bending with the first member 130 outside.

Optionally, the first member 130 may be a window member 135, the second member 110 may be the circularly polarizing function film laminate 115, the third member 170 may be a touch sensor member 175 including a transparent conductive layer 171 formed on a surface closer to the second adhesive layer 140. A second structure 105 may be joined to a surface of the touch sensor member 175 opposite to the second adhesive layer 140 via a third adhesive layer 160.

Optionally, the second structure 105 may include a panel member 150, and the panel member 150 may include a thin film encapsulation layer 151 on a surface closer to the third adhesive layer 160.

Optionally the window member 130 may have a hard coat layer 131 on a surface opposite to the first adhesive layer 120.

Optionally, the circularly polarizing function film laminate 115 may be a laminate of a polarizing film 111 and a retardation film 113. The polarizing film 113 may be a laminate of a polarizer 117 and a polarizer protective film 119 laminated on at least one surface of the polarizer 117. The circularly polarizing function film laminate 115 is provided, for example, for generating circularly polarized light or compensating a view angle in order to prevent light entering inside from a visible side of the polarizing film 111 from being internally reflected and emitted to the visible side.

Optionally the polarizer protective film 111 may contain acrylic resin.

The first structure 101 has one surface joined to the other surface of the second member 110 at least via the second adhesive layer 140, and includes the third member 170 on the surface in contact with the second adhesive layer 140. When the multilayer structure 100 is deformed by bending, tensile stress acts on the third member 170. In the multilayer structure 100, the third member 170 includes, on a surface in contact with the second adhesive layer 140, a layer that has tensile breaking extension lower than that of each of the first member 130 and the second member 110 and is likely to be broken when deformed by bending.

Optionally, the third member 170 may be the touch sensor member 175 including the transparent conductive layer 171 formed on the surface closer to the second adhesive layer 140.

Optionally, the second structure 105 may further include a fourth adhesive layer 180 on a surface of the panel member 150 opposite to the third adhesive layer 160, and a protective member 190 laminated via the fourth adhesive layer 180.

Hardness of each of the first adhesive layer 120 and the second adhesive layer 140 is determined such that when the multilayer structure 100 is deformed by bending, deformation by bending of the one surface of the first member, deformation by bending of the one surface of the second member 110, deformation by bending of the other surface of the second member 110, and deformation by bending of the one surface of the third member 170 interact with one another via the first adhesive layer 120 and the second adhesive layer 140, and that extension of the layer that is likely to be broken when deformed by bending is reduced to a value lower than tensile breaking extension of the layer that is likely to be broken.

Optionally, the hardness of each of the first adhesive layer 120 and the second adhesive layer 140 is determined by a thickness and/or a thickness of each of the first adhesive layer 120 and the second adhesive layer 140.

For example, when A represents a difference between strain in a direction perpendicular to a bending radius direction that occurs in the one surface of the second member 110 and strain in the direction perpendicular to the bending radius direction that occurs in a surface of the first member 130 facing the first adhesive layer 120 in a case where the multilayer structure 100 is folded at an angle of 180° with the first member 130 outside, and deformed by bending such that a distance between outermost surfaces facing parallel to each other of the multilayer structure 100 is 4 mm with the multilayer structure 100 being folded at the angle of 180°, A′ represents a difference between strain in the direction perpendicular to the bending radius direction that occurs in an outer surface of the second member 110 and strain in the direction perpendicular to the bending radius direction that occurs in an inner surface of the first member 130 in a case where the second member 110 and the first member 130 both as single layers are folded at an angle of 180° such that their outer surfaces and inner surfaces when deformed by bending are the same as those when the display device is deformed by bending, and deformed by bending such that a distance between outermost surfaces facing parallel to each other of each of the second member 110 and the first member 130 is 4 mm with the second member 110 and the first member 130 being folded at the angle of 180°, B represents a difference between strain in the direction perpendicular to the bending radius direction that occurs in the other surface of the optical film 110 and strain in the direction perpendicular to the bending radius direction that occurs in a surface of the first structure 101 facing the second adhesive layer 140 in a case where the multilayer structure 100 is folded at the angle of 180° with the first member 130 outside, and deformed by bending such that the distance between the outermost surfaces facing parallel to each other of the multilayer structure 100 is 4 mm with the multilayer structure 100 being folded at the angle of 180°, and B′ represents a difference between strain in the direction perpendicular to the bending radius direction that occurs in an inner surface of the second member 110 and strain in the direction perpendicular to the bending radius direction that occurs in an outer surface of the first structure 101 in a case where the second member 110 and the first structure 101 both as single layers are folded at an angle of 180° such that their outer surfaces and inner surfaces when deformed by bending are the same as those when the display device is deformed by bending, and deformed by bending such that a distance between outermost surfaces facing parallel to each other of each of the second member 110 and the first structure 101 is 4 mm with the second member 110 and the first structure 101 being folded at the angle of 180°, relationships in Expressions (1), (2), and (3) below are satisfied between the differences A, A′, B, and B′ in the strains, and thus extension of the layer that is more likely to be broken when deformed by bending is reduced to a value lower than breaking extension:

0.3<A/A′<1.2 (1)

B/B′<1.7A/A′−0.15 (2)

0<B/B′<1.25 (3).

A represents a difference between strain in the direction perpendicular to the bending radius direction that occurs in the outer surface of the second member 110 and strain in the direction perpendicular to the bending radius direction that occurs in the inner surface of the first member 130 in a case where the second member 110 and the first member 130 with the first adhesive layer 120 therebetween are folded and deformed by bending, and A′ represents a difference between strain in the direction perpendicular to the bending radius direction that occurs in the outer surface of the second member 110 and strain in the direction perpendicular to the bending radius direction that occurs in the inner surface of the first member 130 in a case where the second member 110 and the first member 130 both as single layers are folded and deformed by bending. Thus, it is considered that the value of A/A′ is smaller the harder the first adhesive layer 120 is, that is, the value of A/A′ indicates hardness of the first adhesive layer 120 in the configuration of the multilayer structure 100. Similarly, it is considered that the value of B/B′ is smaller the harder the second adhesive layer 140 is, that is, the value of B/B′ indicates hardness of the second adhesive layer 140 in the configuration of the multilayer structure 100.

In this respect, the present inventors have first found that in a laminate including a plurality of layers and/or members laminated via a plurality of adhesive layers, bending displacements that occur in surfaces of the layers and/or members facing each other via the adhesive layers influence each other via the adhesive layers to influence extension that occurs in the layers and/or members, and noting this, appropriately selecting hardness of each of the plurality of adhesive layers makes it possible to reduce extension of a layer and/or member vulnerable to bending included in the laminate when the laminate is deformed by bending, and to suppress break of the layer and/or member vulnerable to bending. Thus, appropriately selecting hardness of each of the first adhesive layer 120 and the second adhesive layer 140 with reference to A/A′ and B/B′ to satisfy Expressions (1) to (3) that define conditions relating to A/A′ and B/B′, makes it possible to reduce extension of the layer that is likely to be broken when deformed by bending is reduced to a value lower than breaking extension, and to suppress break of the layer that is likely to be broken.

A shear modulus G′ of the adhesive layer is a dominant factor in determining hardness of the adhesive layer, but a thickness of the adhesive layer is also a factor. The adhesive layer is harder for smaller thickness.

Optionally a shear modulus G′ of the second adhesive layer 140 may be higher than a shear modulus G′ of the first adhesive layer 120. In this respect, the present inventors have first found that if a certain adhesive layer is hardened in a laminate including a plurality of layers and/or members laminated via a plurality of adhesive layers, strain in a layer or member laminated on an outer side of the adhesive layer is shifted to a tension side and strain in a layer or member laminated on an inner side of the adhesive layer is shifted to a compression side when the laminate is folded. Since the shear modulus G′ of the adhesive layer is a dominant factor of hardness of the adhesive layer, such a configuration may reduce tensile strain that occurs in the transparent conductive layer 171 and the thin film encapsulation layer 151 that are vulnerable and laminated on the inner side of the second adhesive layer 140.

Optionally a shear modulus G′ of the fourth adhesive layer 180 may be lower than the shear modulus G′ of the second adhesive layer 140 and lower than a shear modulus G′ of the third adhesive layer 160. If the adhesive layer is softened, strain in a layer or member laminated on the outer side of the adhesive layer is shifted to a compression side, and strain in a layer or member laminated on the inner side of the adhesive layer is shifted to a tension side. Since the shear modulus G′ of the adhesive layer is a dominant factor of hardness of the adhesive layer, such a configuration may reduce tensile strain that occurs in the transparent conductive layer 171 and the thin film encapsulation layer 151 that are vulnerable and laminated on the outer side of the fourth adhesive layer 180.

Optionally a relationship of 0.8<A/A′ may be further satisfied between the differences A and A′ in the strains. If the adhesive layer is softened, strain in a layer or member laminated on the outer side of the adhesive layer is shifted to a compression side, and strain in a layer or member laminated on the inner side of the adhesive layer is shifted to a tension side. Since it is considered that the value of A/A′ is smaller the harder the first adhesive layer 120 is, such a configuration may reduce tensile strain that occurs in the hard coat layer 131 laminated on the outer side of the first adhesive layer 120.

### [Method of Manufacturing Multilayer Structure]

As described above, if a certain adhesive layer is hardened in a laminate including a plurality of layers and/or members laminated via a plurality of adhesive layers, strain in a layer or member laminated on the outer side of the adhesive layer is shifted to a tension side and strain in a layer or member laminated on the inner side of the adhesive layer is shifted to a compression side when the laminate is folded. Thus, to suppress break of a layer vulnerable to bending on an inner side of a certain adhesive layer, hardness of the adhesive layer may be increased, and to suppress break of a layer vulnerable to bending on an outer side of the certain adhesive layer, hardness of the adhesive layer may be decreased.

For example, if a layer that is likely to be broken of a first structure on the inner side of the first adhesive layer or the second adhesive layer has been broken or has been expected to be broken in a design of the multilayer structure, hardness of at least one of the first adhesive layer and the second adhesive layer may be increased to suppress break of the layer that is likely to be broken. In this case, since the examples of the factors in determining hardness of the adhesive layer include the shear modulus G′ of the adhesive layer and the thickness of the adhesive layer, decreasing the thickness of at least one of the first adhesive layer and the second adhesive layer or increasing the modulus of at least one of the first adhesive layer and the second adhesive layer may suppress break of the layer that is likely to be broken.

Also, in this case, since the layer that is likely to be broken of the first structure is located on the outer side of the third adhesive layer and the fourth adhesive layer, decreasing hardness of at least one of the third adhesive layer and the fourth adhesive layer, for example, increasing the thickness of the third adhesive layer, and/or decreasing the shear modulus G′ of at least one of the third adhesive layer and the fourth adhesive layer may suppress break of the layer that is likely to be broken.

Based on the above consideration, the method of manufacturing a multilayer structure according to the present invention includes determining whether the layer that is likely to be broken of the third member has been or is to be broken when deformed by bending with the first member of the multilayer structure outside, and when it is determined that the layer that is likely to be broken of the third member has been or is to be broken, increasing the hardness of at least one of the first adhesive layer and the second adhesive layer, thereby manufacturing the multilayer structure such that extension of the layer that is likely to be broken of the third member when deformed by bending is reduced to a value lower than the tensile breaking extension of the layer that is likely to be broken.

Optionally, increasing the hardness of at least one of the first adhesive layer and the second adhesive layer may be increasing the modulus of at least one of the first adhesive layer and the second adhesive layer and/or reducing the thickness of at least one of the first adhesive layer and the second adhesive layer.

Optionally, the method may further include determining whether the layer that is likely to be broken of the third member has been or is to be broken when deformed by bending, and when it is determined that the layer that is likely to be broken of the third member has been or is to be broken, reducing the hardness of the third adhesive layer, thereby manufacturing the multilayer structure such that extension of the layer that is likely to be broken of the third member when deformed by bending is reduced to a value lower than the tensile breaking extension of the layer that is likely to be broken.

Optionally, reducing the hardness of the third adhesive layer may be reducing the modulus of the third adhesive layer and/or increasing the thickness of the third adhesive layer.

Optionally, the method may further include determining whether the transparent conductive layer has been or is to be broken when deformed by bending, and when it is determined that the transparent conductive layer has been or is to be broken, reducing the hardness of at least one of the third adhesive layer and the fourth adhesive layer, thereby manufacturing the multilayer structure such that extension of the transparent conductive layer when deformed by bending is reduced to a value lower than the tensile breaking extension of the transparent conductive layer.

Optionally, reducing the hardness of the fourth adhesive layer may be reducing the modulus of the third adhesive layer and/or increasing the thickness of the third adhesive layer.

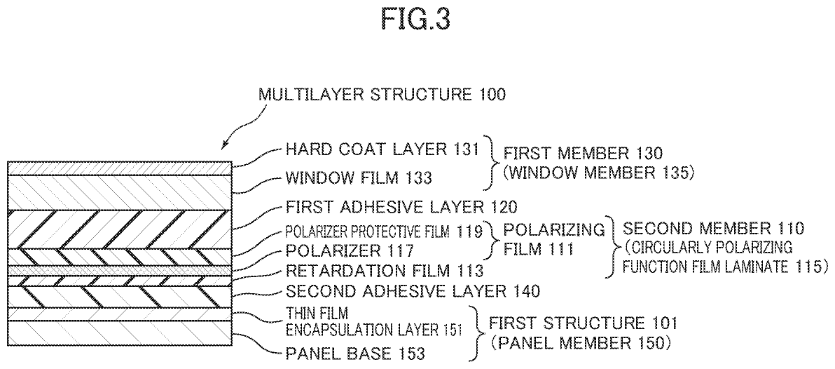

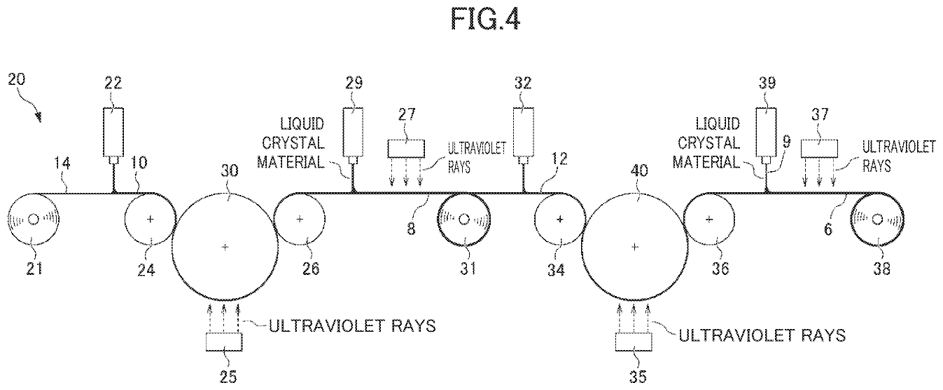

A multilayer structure in FIG. 3 is essentially the same as that in FIG. 2, but is different in that in the multilayer structure in FIG. 3, the layer that has tensile breaking extension lower than that of each of the first member 130 and the second member 110 and is likely to be broken when deformed by bending is the transparent conductive layer 171 formed on the surface of the touch sensor member 170 opposite to the panel member 150, the touch sensor member 170 being laminated between the second adhesive layer 140 and the panel member 150, while in the multilayer structure in FIG. 4, the layer that has tensile breaking extension lower than that of each of the first member 130 and the second member 110 and is likely to be broken when deformed by bending is the thin film encapsulation layer 151 formed on the surface of the panel member 150 closer to the second adhesive layer 140.

### EXAMPLES

The multilayer structure according to the present invention will be further described using examples below. The multilayer structure according to the present invention are not limited to the examples.

### Example 1

### [Polarizer]

An amorphous polyethylene terephthalate (hereinafter, also referred to as “PET”) (IPA copolymerized PET) film (thickness: 100 μm) having 7 mol % of isophthalic acid unit was prepared as a thermoplastic resin substrate, and the surface was corona treated (58 W/m²/min). On the other hand, PVA (polymerization degree: 4200, saponification degree: 99.2%) with 1% by weight of acetoacetyl-modified PVA (trade name: GOCEFIMER Z200, manufactured by Nippon Synthetic Chemical Industry Co., Ltd., (average polymerization degree: 1200, saponification degree: 98.5 mol %, acetoacetylation degree: 5 mol %) being added was prepared to prepare a coating solution of a PVA aqueous solution containing 5.5% by weight of PVA resin, the coating solution was applied such that a thickness after drying was 12 μm, and dried for 10 minutes by hot-air drying under an atmosphere of 60° C. to produce a laminate having a layer of PVA resin on the substrate.

Then, this laminate was first subjected to free end stretching at a temperature of 130° C. in air by 1.8 times (auxiliary in-air stretching) to produce a stretched laminate. Then, the stretched laminate was immersed in a boric acid insolubilizing aqueous solution at a liquid temperature of 30° C. for 30 seconds to insolubilize the PVA layer in which PVA molecules contained in the stretched laminate were oriented. The boric acid insolubilizing aqueous solution in this step contained 3 parts by weight of boric acid with respect to 100 parts by weight of water. This stretched laminate was dyed to produce a colored laminate. The colored laminate was produced in such a manner that the stretched laminate was immersed for any time in a dye solution containing iodine and potassium iodide at a liquid temperature of 30° C. such that single layer transmittance of the PVA layer forming a polarizer to be finally produced was 40% to 44% to dye the PVA layer included in the stretched laminate with iodine. In this step, the dye solution contained water as a solvent, iodine at a concentration of 0.1% to 0.4% by weight, and potassium iodide at a concentration of 0.7% to 2.8% by weight. A ratio of the concentration of iodine to potassium iodide was 1 to 7. Then, the colored laminate was immersed in a boric acid crosslinking aqueous solution at 30° C. for 60 seconds to cross-link the PVA molecules in the PVA layer having absorbed iodine. The boric acid crosslinking aqueous solution in this step contained 3 parts by weight of boric acid with respect to 100 parts by weight of water, and 3 parts by weight of potassium iodide with respect to 100 parts by weight of water.

Further, the colored laminate obtained was stretched in a boric acid aqueous solution at a stretching temperature of 70° C. by 3.05 times (in-boric-acid-solution stretching) in the same direction as the previous stretching in the air to obtain an optical film laminate having a final stretching ratio of 5.50. The optical film laminate was taken out of the boric acid aqueous solution, and the boric acid adhering to the surface of the PVA layer was washed with an aqueous solution containing 4 parts by weight of potassium iodide with respect to 100 parts by weight of water. The optical film laminate washed was dried by a drying step with hot air at 60° C. The thickness of the polarizer included in the optical film laminate obtained was 5 μm.

### [Polarizer Protective Film]

A polarizer protective film used was obtained in such a manner that methacrylic resin pellet having a glutarimide ring unit was extruded and formed into a film shape and stretched. This polarizer protective film had a thickness of m and was an acrylic film having moisture permeability of 160 g/m².

### [Polarizing Film]

Then, the polarizer and the polarizer protective film were bonded to each other using an adhesive mentioned below to obtain a polarizing film.

As the adhesive (active energy ray curable adhesive), components were mixed according to the recipe listed in Table 1 and stirred at 50° C. for 1 hour to prepare an adhesive (active energy ray curable adhesive A). The numerical values in the table are blending amounts (addition amounts) and indicate solid contents or solid content ratios (based on weight) in % by weight when a total amount of composition is 100% by weight. The components listed below were used:

HEAA: hydroxyethyl acrylamide

M-220: ARONIX M-220, tripropylene glycol diacrylate, manufactured by Toagosei Co., Ltd.

ACMO: acryloyl morpholine

AAEM: 2-acetoacetoxyethyl methacrylate, manufactured by Nippon Synthetic Chemical Industry Co., Ltd.

UP-1190: ARUFON UP-1190, manufactured by Toagosei Co., Ltd.

IRG 907: IRGACURE 907, 2-methyl-1-(4-methylthiophenyl)-2-morpholinopropan-1-one, manufactured by BASF SE

DETX-S: KAYACURE DETX-S, diethylthioxanthone, manufactured by Nippon Kayaku Co., Ltd.

TABLE 1

| (% BY | COMPOSITION |
|---|---|
| WEIGHT) | OF ADHESIVE |
| HEAA | 11.4 |
| M-220 | 57.1 |
| ACMO | 11.4 |
| AAEM | 4.8 |
| UP-1190 | 11.4 |
| IRG907 | 2.8 |
| DETX-S | 1.3 |

In the examples and comparative examples using the adhesive, after the polarizer protective film and the polarizer were laminated with the adhesive, the adhesive was cured by being irradiated with ultraviolet rays to form the adhesive layer. For irradiating with the ultraviolet rays, a gallium-filled metal halide lamp was used (trade name “Light HAMMER 10”, manufactured by Fusion UV Systems, Inc., bulb: V bulb, peak illuminance: 1600 mW/cm², integrated amount of irradiation: 1000/mJ/cm² (wavelength 380 to 440 nm)).

### [Retardation Film]

A retardation film (quarter wave retardation plate) in this example included two layers: a retardation layer for quarter wave plate and a retardation layer for half wave plate, in which a liquid crystal material was oriented and solidified. Specifically the retardation film was manufactured as descried below.

### (Liquid Crystal Material)

As a material for forming the retardation layer for half wave plate and the retardation layer for quarter wave plate, a polymerizable liquid crystal material (trade name: Paliocolor LC242, manufactured by BASF SE) exhibiting a nematic liquid crystal phase was used. A photopolymerization initiator (trade name: IRGACURE 907, manufactured by BASF SE) for the polymerizable liquid crystal material was dissolved in toluene. Further, to improve a coating property, MEGAFACE series manufactured by DIC CORPORATION was added by about 0.1% to 0.5% depending on a thickness of the liquid crystal to prepare a liquid crystal coating solution. The liquid crystal coating solution was applied onto an orientation substrate by a bar coater, dried by heating at 90° C. for 2 minutes, and then oriented and solidified by ultraviolet curing under a nitrogen atmosphere. A substrate to which a liquid crystal coating layer might be transferred later, such as PET, was used. Furthermore, to improve the coating property a fluorine polymer of MEGAFACE series manufactured by DIC CORPORATION was added by about 0.1% to 0.5% depending on the thickness of the liquid crystal layer, and methyl isobutyl ketone (MIBK), cyclohexanone, or a mixture of MIBK and cyclohexanone was dissolved at a solid concentration of 25% to prepare a coating solution. The coating solution was applied onto the substrate by a wire bar, dried at 65° C. for 3 minutes, and oriented and solidified by ultraviolet curing under a nitrogen atmosphere. A substrate to which a liquid crystal coating layer might be transferred later, such as PET, was used.

### (Manufacturing Process)

With reference to FIG. 4, a manufacturing process in this example will be described. In this manufacturing process 20, a substrate 14 was provided by a roll, and the substrate 14 was supplied from a supply reel 21. In the manufacturing process 20, the substrate 14 was coated with a coating solution of ultraviolet curable resin 10 by a die 22. In the manufacturing process 20, a roll plate 30 was a cylindrical shaping mold in which an irregular shape relating to an orientation film for quarter wave plate of the quarter wave retardation plate was formed on its circumferential surface. In the manufacturing process 20, the substrate 14 coated with the ultraviolet curable resin was pressed against the circumferential surface of the roll plate 30 by a pressure roller 24, and the ultraviolet curable resin was irradiated with ultraviolet rays by an ultraviolet irradiation device 25 including a high pressure mercury arc lamp, and cured. Thus, in the manufacturing process 20, the irregular shape formed on the circumferential surface of the roll plate 30 was transferred to the substrate 14 at 75° with respect to an MD direction. Then, the substrate 14 was peeled, by a peeling roller 26, from the roll plate 30 integrally with the ultraviolet curable resin cured, and coated with a liquid crystal material by a die 29. Then, the liquid crystal material was cured by irradiation with ultraviolet rays by an ultraviolet irradiation device 27, thereby producing a configuration relating to the retardation layer for quarter wave plate.

Subsequently in this process 20, the substrate 14 was conveyed to a die 32 by a conveying roller 31, and the retardation layer for quarter wave plate of the substrate 14 was coated with a coating solution of ultraviolet curable resin 12 by the die 32. In this manufacturing process 20, a roll plate 40 was a cylindrical shaping mold in which an irregular shape relating to an orientation film for half wave plate of the half wave retardation plate was formed on its circumferential surface. In the manufacturing process 20, the substrate 14 coated with the ultraviolet curable resin was pressed against the circumferential surface of the roll plate 40 by a pressure roller 34, and the ultraviolet curable resin was irradiated with ultraviolet rays by an ultraviolet irradiation device 35 including a high pressure mercury arc lamp, and cured. Thus, in the manufacturing process 20, the irregular shape formed on the circumferential surface of the roll plate 40 was transferred to the substrate 14 at 15° with respect to the MD direction. Then, the substrate 14 was peeled, by a peeling roller 36, from the roll plate 40 integrally with the ultraviolet curable resin 12 cured, and coated with a liquid crystal material by a die 39. Then, the liquid crystal material was cured by irradiation with ultraviolet rays by an ultraviolet light irradiation device 37, thereby producing a configuration relating to the retardation layer for half wave plate, and obtaining a retardation film having a thickness of 7 μm and including the two layers: the retardation layer for quarter wave plate and the retardation layer for half wave plate.

### [Second Member (Circularly Polarizing Function Film Laminate)]

The retardation film and the polarizing film obtained as described above were continuously bonded using the above adhesive by a roll-to-roll method to produce a laminated film (circularly polarizing function film laminate) such that an angle between a slow axis and an absorption axis was 45°.

### [First Adhesive Layer]

An adhesive layer that forms a first adhesive layer in this example was produced by a method described below.

### <Preparation of Acrylic Oligomer>

### <Oligomer A>

60 parts by weight of dicyclopentanyl methacrylate (DCPMA) and 40 parts by weight of methyl methacrylate (MMA) as monomer components, 3.5 parts by weight of α-thioglycerol as a chain transfer agent, and 100 parts by weight of toluene as a polymerization solvent were mixed and stirred at 70° C. for 1 hour under a nitrogen atmosphere. Then, 0.2 parts by weight of 2,2′-azobisisobutyronitrile (AIBN) was added as a thermal polymerization initiator, and the mixture was reacted at 70° C. for 2 hours and then raised to 80° C. and reacted for 2 hours. Then, the reaction solution was heated to 130° C., the toluene, the chain transfer agent, and any unreacted monomers were dried and removed to obtain solid acrylic oligomer (oligomer A). A weight average molecular weight of the oligomer A was 5100, and a glass transition temperature (Tg) was 130° C.

### <Oligomer B>

Solid acrylic oligomer (oligomer B) was obtained in the same manner as the oligomer A except that the monomer components were changed to 60 parts by weight of dicyclohexyl methacrylate (CHMA) and 40 parts by weight of butyl methacrylate (BMA). A weight average molecular weight of the oligomer B was 5000, and a glass transition temperature (Tg) was 44° C.

### (Polymerization of Prepolymer)

43 parts by weight of lauryl acrylate (LA), 44 parts by weight of 2-ethyl hexyl acrylate (2EHA), 6 parts by weight of 4-hydroxybutyl acrylate (4HBA), and 7 parts by weight of N-vinyl-2-pyrolidone (NVP) as monomer components for forming prepolymer, and 0.015 parts by weight of “IRGACURE 184” manufactured by BASF SE as a photopolymerization initiator were blended and irradiated with ultraviolet rays for polymerization to obtain a prepolymer composition (polymerization rate: about 10%).

### (Preparation of Adhesive Composition)

To 100 parts by weight of the prepolymer composition, 0.07 parts by weight of 1,6-hexanediol diacrylate (HDDA), 1 parts by weight of the oligomer A described above, and 0.3 parts by weight of silane coupling agent (“KBM403” manufactured by Shin-Etsu Chemical Co., Ltd.) were added as additive components, which were homogenously mixed to prepare an adhesive composition. This adhesive composition will be hereinafter also referred to as adhesive composition 1.

### (Production of Adhesive Sheet)

A polyethylene terephthalate (PET) film having a thickness of 75 m (“Diafoil MRF75” manufactured by Mitsubishi Chemical Corporation) with a silicone release layer on its surface was used as a substrate (and also a heavy release film), and the substrate was coated with the photocurable adhesive composition described above to a thickness of 50 μm to form a coating layer. Onto this coating layer, a PET film having a thickness of 75 μm (“Diafoil MRF75” manufactured by Mitsubishi Chemical Corporation) having one surface subjected to silicone release treatment was bonded as a cover sheet (and also a light release film). This laminate was irradiated with ultraviolet rays, from the cover sheet side, by a black light position-adjusted such that irradiation intensity on an irradiation surface immediately below a lamp was 5 mW/cm² for photocuring to obtain an adhesive sheet having a thickness of 50 μm. An adhesive layer having any thickness of the adhesive composition 1 produced by the same method will be hereinafter also referred to as adhesive layer 1.

### [Second Adhesive Layer]

An adhesive layer that forms a second adhesive layer in this example was produced under the same condition as the first adhesive layer except that the thickness was 15 μm.

### [Third Adhesive Layer]

An adhesive layer that forms a third adhesive layer in this example was produced by a method described below.

### <Preparation of (Meth)Acrylic Polymer A1>

In a four-necked flask including a stirring blade, a thermometer, a nitrogen gas inlet tube, and a cooler, a monomer mixture containing 99 parts by weight of butyl acrylate (BA) and 1 part by weight of 4-hydroxybutyl acrylate (HBA) were charged.

Further, into 100 parts by weight of the monomer mixture (solid content), 0.1 parts by weight of 2,2′-azobisisobutyronitrile as a polymerization initiator was charged together with acetic ethyl, which were gently stirred while nitrogen gas being introduced for nitrogen substitution, and then polymerization reaction was performed for 7 hours with a liquid temperature in the flask being maintained at about 55° C. Then, acetic ethyl was added to the reaction solution obtained to prepare a (meth)acrylic polymer A1 solution having a weight average molecular weight of 1,600,000 adjusted to a solid content concentration of 30%.

### <Preparation of Acrylic Adhesive Composition>

Into 100 parts by weight (solid content) of the (meth)acrylic polymer A1 solution obtained, 0.1 parts by weight of isocyanate crosslinker (trade name: TAKENATE D110N, trimethylol propane xylylene diisocyanate, manufactured by Mitsui Chemicals, Inc.), 0.3 parts by weight of benzoyl peroxide as a peroxide crosslinker (trade name: NYPER BMT, manufactured by NOF Corporation), and 0.08 parts by weight of silane coupling agent (trade name: KBM403, manufactured by Shin-Etsu Chemical Co., Ltd.) were blended to prepare an acrylic adhesive composition. This adhesive composition will be hereinafter also referred to as adhesive composition 2.

### <Production of Adhesive Sheet>

The acrylic adhesive composition was uniformly applied, by a fountain coater, onto a surface of a polyethylene terephthalate film (PET film, transparent substrate, separator) having a thickness of 38 μm and treated with a silicone release agent, and dried for 2 minutes in an air circulating thermostatic oven at 155° C. to form an adhesive layer (third adhesive layer) having a thickness of 20 m on the surface of the substrate. Onto this coating layer, a polyethylene terephthalate film (PET film, transparent substrate, separator) having a thickness of 38 μm and having one surface subjected to silicone release treatment was bonded as a cover sheet (and also a light release film). An adhesive layer having any thickness of the adhesive composition 2 produced by the same method will be hereinafter also referred to as adhesive layer 2.

### [Fourth Adhesive Layer]

An adhesive layer that forms a fourth adhesive layer in this example was produced under the same condition as the first adhesive layer except that the thickness was 25 μm.

### [First Member (Window Member)]

As a window member as a first member, a transparent polyimide film (product name: “C_50”, manufactured by KOLON INDUSTRIES. INC., thickness 50 μm) as a window film having one surface provided with an acrylic hard coat layer (thickness 10 μm) was used (this window film will be hereinafter also referred to as “window film 1”).

The hard coat layer was formed using a coating agent for hard coat layer. More specifically the coating agent was first applied onto one surface of the transparent polyimide film to form a coating layer, and the coating layer together with the transparent polyimide film was heated at 90° C. for 2 minutes. Then, the coating layer was irradiated with ultraviolet rays by a high pressure mercury lamp at integrated light intensity of 300 mJ/cm² to form a hard coat layer. The window member was produced in this manner.

The coating agent for hard coat layer was prepared by mixing 100 parts by mass of polyfunctional acrylate (product name: “Z-850-16”, manufactured by Aica Kogyo Co., Ltd.) as base resin, 5 parts by mass of leveling agent (trade name: GRANDIC PC-4100, manufactured by DIC CORPORATION), and 3 parts by mass of photopolymerization initiator (trade name: IRGACURE 907, manufactured by Ciba Japan K.K.), and diluting the mixture with methylisobutyl ketone to a solid content concentration of 50% by mass.

### [Third Member (Touch Sensor Member)]

As a transparent resin substrate, a cycloolefin resin substrate (“ZEONOR”, manufactured by Zeon Corporation, thickness 25 m, in-plane birefringence index 0.0001) was prepared.

Then, a diluted solution of a hard coat composition containing binder resin was applied onto an upper surface of the transparent resin substrate, a diluted solution of a hard coat composition containing binder resin and a plurality of particles was applied onto a lower surface of the transparent resin substrate. Then, the diluted solutions were dried, and then the upper and lower surfaces were irradiated with ultraviolet rays to cure the hard coat composition. Thus, a first cured resin layer (thickness 1 μm) containing no particles was formed on the upper surface of the transparent resin substrate, and a second cured resin layer (thickness 1 μm) containing particles was formed on the lower surface of the transparent resin substrate.

As the particles, crosslinking acrylic styrene resin particles (“SSX105” manufactured by Sekisui Jushi Corporation, diameter 3 μm) were used. As the binder resin, urethane polyfunctional polyacrylate (“UNIDIC” manufactured by DIC CORPORATION) was used.

Then, a diluted solution of an optical adjustment composition containing zirconia particles and ultraviolet curable resin (“OPSTAR Z7412” manufactured by JSR Corporation, refractive index 1.62) was applied onto an upper surface of the first cured resin layer, dried at 80° C. for 3 minutes, and then irradiated with ultraviolet rays. Thus, an optical adjustment layer (thickness 0.1 μm) was formed on the upper surface of the first cured resin layer.

Then, an ITO layer (thickness 40 nm) as an amorphous transparent conductive layer was formed on an upper surface of the optical adjustment layer by sputtering.

Thus, an amorphous transparent conductive film was produced sequentially including the second cured resin layer, the transparent resin substrate, the first cured resin layer, the optical adjustment layer, and the amorphous transparent conductive layer.

Then, the amorphous transparent conductive film obtained was heated at 130° C. for 90 minutes to crystallize the ITO layer.

### [Panel Member]

As a panel base, a polyimide resin film (“UPILEX” manufactured by UBE INDUSTRIES. LTD., thickness 25 μm) made of biphenyltetracarboxylic dianhydride (BPDA) was prepared.

Then, an ITO layer (thickness 40 nm) as an amorphous transparent conductive layer was formed on an upper surface of the polyimide resin film by sputtering.

Then, the amorphous transparent conductive film obtained was heated at 130° C. for 90 minutes to crystallize the ITO layer.

Then, the ITO layer and the transparent conductive film with the ITO layer obtained were used as dummies of a thin film encapsulation layer and a panel member, respectively. The ITO layer as the dummy of the thin film encapsulation layer will be hereinafter also referred to as “thin film encapsulation layer alternate ITO layer” or “alternate ITO layer”.

### [Protective Member]

As a protective member in this example, a polyimide resin substrate (“UPILEX” manufactured by UBE INDUSTRIES. LTD., thickness 50 μm) made of biphenyltetracarboxylic dianhydride (BPDA) was used.

Various evaluations of the members, layers, and films obtained were made as described below. Tables 2-1 to 2-3 show properties of the adhesive layers, hard coat layer, polarizer protective film, ITO layer, and alternate ITO layer obtained.

### Example 2

Members, layers, films, and a laminate were manufactured and produced under the same condition as in Example 1 except that adhesive composition 2 was used as an adhesive composition of an adhesive layer that forms the second adhesive layer, and various evaluations were made as described below. Tables 2-1 to 2-3 show properties of the adhesive layers, hard coat layer, polarizer protective film, ITO layer, and alternate ITO layer obtained.

### Example 3

Members, layers, films, and a laminate were manufactured and produced under the same condition as in Example 1 except that an adhesive layer described below was used as an adhesive layer that forms the second adhesive layer, and various evaluations were made as described below. Tables 2-1 to 2-3 show properties of the adhesive layers, hard coat layer, polarizer protective film, ITO layer, and alternate ITO layer obtained.

The adhesive layer that forms the second adhesive layer in this example was produced by a method described below.

### <Preparation of (Meth)Acrylic Polymer A3>

Preparation of (meth)acrylic polymer A3 was performed in the same manner as the preparation of the (meth)acrylic polymer A1 except that polymerization reaction was performed for 7 hours with a liquid temperature in a flask being maintained at about 55° C. such that a blend ratio (weight ratio) between acetic ethyl and toluene was 95/5.

### <Preparation of Acrylic Adhesive Composition>

Into 100 parts by weight (solid content) of the (meth)acrylic polymer A3 solution obtained, 0.15 parts by weight of trimethylol propane/tolylenediisocyanate (trade name: Coronate L, manufactured by Nippon Polyurethane Industry Co., Ltd.) and 0.08 parts by weight of silane coupling agent (trade name: KBM403, manufactured by Shin-Etsu Chemical Co., Ltd.) were blended to prepare an acrylic adhesive composition. This adhesive composition will be hereinafter also referred to as adhesive composition 3.

### <Production of Adhesive Sheet>

The acrylic adhesive composition was uniformly applied, by a fountain coater, onto a surface of a polyethylene terephthalate film (PET film, transparent substrate, separator) having a thickness of 38 μm and treated with a silicone release agent, and dried for 2 minutes in an air circulating thermostatic oven at 155° C. to form an adhesive layer (second adhesive layer) having a thickness of 15 m on the surface of the substrate. Onto this coating layer, a polyethylene terephthalate film (PET film, transparent substrate, separator) having a thickness of 38 μm and having one surface subjected to silicone release treatment was bonded as a cover sheet (and also a light release film). An adhesive layer having any thickness of the adhesive composition 3 produced by the same method will be hereinafter also referred to as adhesive layer 3.

### Example 4

Members, layers, films, and a laminate were manufactured and produced under the same condition as in Example 1 except that an adhesive layer described below was used as an adhesive layer that forms the second adhesive layer and that a multilayer structure was produced as described below, and various evaluations were made as described below. Tables 2-1 to 2-3 show properties of the adhesive layers, hard coat layer, polarizer protective film, ITO layer, and alternate ITO layer obtained.

The adhesive layer that forms the second adhesive layer in this example was produced by a method described below.

63 parts by weight of acrylic acid 2-ethyl hexyl (2EHA), 15 parts by weight of N-vinyl-2-pyrolidone (NVP), 9 parts by weight of methyl methacrylate (MMA), and 13 parts by weight of acrylic acid 2-hydroxyethyl (HEA) as monomer components, 0.2 parts by weight of 2,2′-azobisisobutyronitrile as a polymerization initiator, and 133 parts by weight of acetic ethyl as a polymerization solvent were charged into a separable flask, and stirred for 1 hour while nitrogen gas being introduced. After oxygen in a polymerization system was removed in this manner, the temperature was increased to 65° C. to cause reaction for 10 hours, and then acetic ethyl was added to obtain an acrylic polymer solution having a solid content concentration of 30% by weight. A weight average molecular weight of acrylic polymer in the acrylic polymer solution was 800,000.

Then, to the acrylic polymer solution, 1.1 parts by weight (solid content) of isocyanate crosslinker (trade name: “TAKENATE D110N”, manufactured by Mitsui Chemicals, Inc.) with respect to 100 parts by weight of acrylic polymer (solid content) was added and mixed to prepare an adhesive composition. This adhesive composition will be hereinafter also referred to as adhesive composition 4.

### <Production of Adhesive Sheet>

A surface of a polyethylene terephthalate film (PET film, transparent substrate, separator) having a thickness of 38 μm and treated with a silicone release agent was uniformly coated by a fountain coater. Then, the coating layer formed on the PET substrate was placed in an oven and dried for 3 minutes at 130° C. to form an adhesive sheet having an adhesive layer with a thickness of 15 m on one surface of the PET substrate. Onto this coating layer, a polyethylene terephthalate film (PET film, transparent substrate, separator) having a thickness of 38 μm and having one surface subjected to silicone release treatment was bonded as a cover sheet (and also a light release film). An adhesive layer having any thickness of the adhesive composition 4 produced by the same method will be hereinafter also referred to as adhesive layer 4.

The multilayer structure in this example was produced by a method described below.

An adhesive layer was transferred from a release film to one of members that sandwich the adhesive layer therebetween, and the members were laminated to sandwich the adhesive layer therebetween and pressed by a hand roller. A rectangular sample having a width of 30 mm and a length of 100 mm was cut out from the laminate obtained to produce an evaluation sample including the members laminated via the adhesive layer.

### Examples 5 to 7, 9, 10, 12, 13, 19, 22, 27, and 28, Comparative Example 3

Members, layers, films, and a laminate were manufactured and produced under the same condition as in Example 1 except that the combination of the types of the adhesive layers (adhesive layers 1 to 4) that form the first adhesive layer, second adhesive layer, third adhesive layer, and fourth adhesive layer were changed as shown in Tables 2-1 to 2-3, and various evaluations were made as described below. Table 2 shows properties of the adhesive layers, hard coat layer, polarizer protective film, ITO layer, and alternate ITO layer obtained.

### Examples 21 and 23

Members, layers, films, and a laminate were manufactured and produced under the same condition as in Example 1 except that the combination of the types of the adhesive layers (adhesive layers 1 to 4) that form the first adhesive layer, second adhesive layer, third adhesive layer, and fourth adhesive layer were changed as shown in Table 2 and that the thickness of the first adhesive layer was m, and various evaluations were made as described below. Table 2 shows properties of the adhesive layers, hard coat layer, polarizer protective film, ITO layer, and alternate ITO layer obtained.

### Examples 8, 11, 15 to 18, 20, 24 to 26, Comparative Examples 1, 2, 4, and 5

Members, layers, films, a laminate and a multilayer structure were manufactured and produced under the same condition as in Example 4 except that the combination of the types of the adhesive layers (adhesive layers 1 to 4) that form the first adhesive layer, second adhesive layer, third adhesive layer, and fourth adhesive layer were changed as shown in Table 2, and various evaluations were made as described below. Table 2 shows properties of the adhesive layers, hard coat layer, polarizer protective film, ITO layer, and alternate ITO layer obtained.

### Examples 29 to 31, Comparative Example 5

Members, layers, films, and a laminate were manufactured and produced under the same condition as in Example 1 except that the combination of the types of the adhesive layers (adhesive layers 1 to 4) that form the first adhesive layer, second adhesive layer, third adhesive layer, and fourth adhesive layer were changed as shown in Table 2 and that “Kapton(R) type H” (product name) manufactured by DU PONT-TORAY CO., LTD. was used as a transparent polyimide film as a window film of a window member (this window film will be hereinafter also referred to as “window film 2”), and various evaluations were made as described below. Tables 2-1 to 2-3 show properties of the adhesive layers, hard coat layer, polarizer protective film, ITO layer, and alternate ITO layer obtained.

### Example A1

As described later in sections of (Simulation of difference in strain in direction perpendicular to bending radius direction) and (Evaluation of occurrence of cracking), the multilayer structure produced in Comparative Example 1 was deformed by bending with the first member (window member) outside, and it was determined whether the ITO layer as a layer that was likely to be broken of the third member (touch sensor member) had been or was to be broken. As shown in Tables 2-1 to 2-3, simulation expected that the ITO layer was to be broken, and the ITO layer was actually broken.

Then, the adhesive layer that forms the second adhesive layer was changed from the adhesive layer 1 to the adhesive layer 4 having a higher shear modulus G′ to manufacture a multilayer structure of Example 11.

### Example A2

As described later in the sections of (Simulation of difference in strain in direction perpendicular to bending radius direction) and (Evaluation of occurrence of cracking), the multilayer structure produced in Comparative Example 2 was deformed by bending with the first member (window member) outside, and it was determined whether the ITO layer as a layer that was likely to be broken of the second member (touch sensor member) had been or was to be broken. As shown in Tables 2-1 to 2-3, simulation expected that the ITO layer was to be broken, and the ITO layer was actually broken.

Then, the adhesive layer that forms the second adhesive layer was changed from the adhesive layer 1 to the adhesive layer 4 having a higher shear modulus G′ to manufacture a multilayer structure of Example 14.

### Example B1

As described later in the sections of (Simulation of difference in strain in direction perpendicular to bending radius direction) and (Evaluation of occurrence of cracking), the multilayer structure produced in Comparative Example 1 was deformed by bending with the first member (window member) outside, and it was determined whether the ITO layer as a layer that was likely to be broken of the third member (touch sensor member) had been or was to be broken. As shown in Tables 2-1 to 2-3, simulation expected that the ITO layer was to be broken, and the ITO layer was actually broken.

Then, the adhesive layer that forms the third adhesive layer was changed from the adhesive layer 4 to the adhesive layer 1 having a lower shear modulus G′ to manufacture a multilayer structure of Example 25.

### Example C1

As described later in the sections of (Simulation of difference in strain in direction perpendicular to bending radius direction) and (Evaluation of occurrence of cracking), the multilayer structure produced in Comparative Example 2 was deformed by bending with the first member (window member) outside, and it was determined whether the ITO layer as a layer that was likely to be broken of the third member (touch sensor member) had been or was to be broken. As shown in Tables 2-1 to 2-3, simulation expected that the ITO layer was to be broken, and the ITO layer was actually broken.

Then, the adhesive layer that forms the fourth adhesive layer was changed from the adhesive layer 2 to the adhesive layer 1 having a lower shear modulus G′ to simulate a multilayer structure of Example 5.

### [Evaluation]

### (Measurement of Thickness)

The thicknesses of the polarizer, polarizer protective film, retardation film, adhesive layers, transparent film, window film, protective member, and the like were measured using a dial gauge (manufactured by Mitutoyo Corporation). The thicknesses of the ITO layer and alternate ITO layer were measured based on an image taken by transmission electron microscopy (TEM).

### (Measurement of Shear Modulus G′ of Adhesive Layer)

The separators were peeled from the adhesive sheets in the examples and comparative examples, and the plurality of adhesive sheets were laminated to produce a test sample having a thickness of about 1.5 mm. This test sample was punched out into a disk shape having a diameter of 7.9 mm, sandwiched between parallel plates, and subjected to dynamic viscoelasticity measurement under the conditions described below using “Advanced Rheometric Expansion System (ARES)” manufactured by Rheometric Scientific Co., Ltd., and a shear modulus G′ was read from the measurement result.

### (Measurement Conditions)

Deformation mode: torsion

Measurement temperature: −40° C. to 150° C.

Heating rate: 5° C./min

Measurement frequency: 1 Hz

### (Measurement of Strain and Stress)

A sample having a width of 10 mm and a length of 100 mm was cut out from each of the substrate film of the touch sensor member, the alternate base film of the panel member, the film of the protective member, and the window film, polarizer, polarizer protective film, adhesive layer 1, adhesive layer 2, adhesive layer 3, and adhesive layer 4 obtained. Each sample obtained was placed in a tensile testing machine (product name: “Autograph AG-IS”, manufactured by Shimadzu Corporation), strain and stress when the sample was drawn at 200 mm/min were measured to obtain a strain-stress curve. The stress was calculated in Pa from the thickness and the width. Each adhesive layer included a plurality of laminated adhesive layers and had a thickness of 100 μm.

If it is difficult to produce the adhesive layer having a thickness of 100 μm, the strain-stress curve may be also obtained by methods described below:

1. A strain-stress curve for a certain sample is previously calculated by the method described above, and the curve is divided by tensile modulus calculated from a slope of the curve within a range of strain of 0.05% to 0.25% to create a normalized strain-stress curve.
2. A shear modulus G′ of a sample to be measured is measured and obtained by the method described above.
3. A component of a sample to be measured is measured to calculate a Poisson's ratio v.
4. Since a relational expression: E′=2G′(1+v) is satisfied between a tensile modulus E′ and a shear modulus G′, E′ is calculated from G′ and v measured in items 2 and 3 above.
5. The normalized strain-stress curve created in item 1 above may be multiplied by the tensile modulus E′ calculated in item 4 above to obtain a strain-stress curve of a sample to be measured.

### (Simulation of Difference in Strain in Direction Perpendicular to Bending Radius Direction)

Based on the strain-stress curve obtained of each of the members and films, strain in a direction perpendicular to a bending radius direction of each of the members, layers, and films when deformed by bending in each of the examples and comparative examples was calculated by simulation to calculate A/A′, B/B′, and 1.7A/A′-0.15. Tables 2-1 to 2-3 show the results.

### <Computer Simulation Software>

As simulation software, Marc as a non-linear finite analysis software manufactured by MSC Software Corporation was used.

### <Model>

### 1. Layer Structure

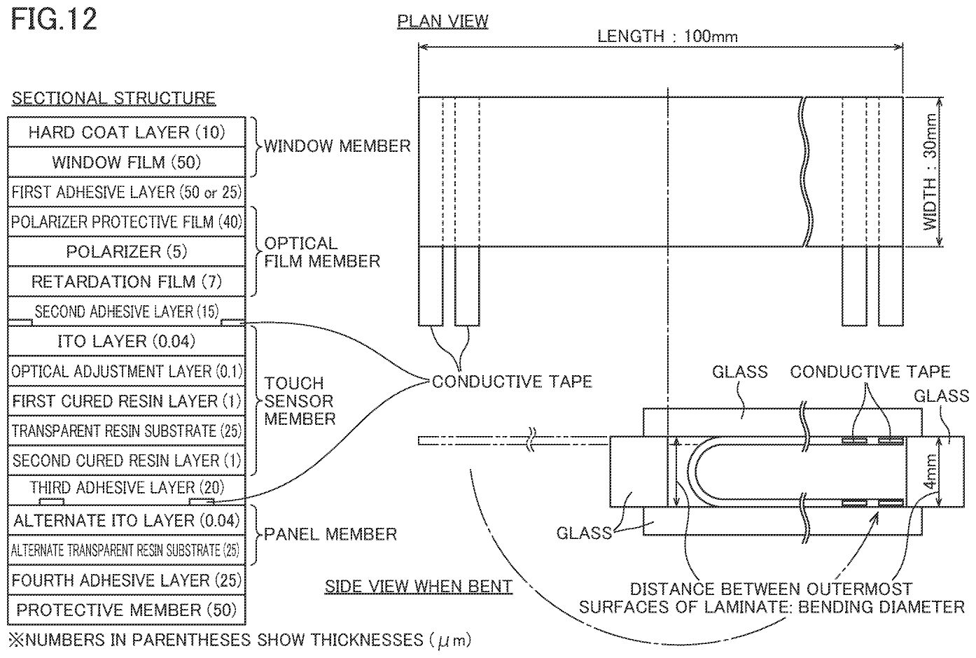

A layer structure of a model was the same as a sectional structure of a multilayer structure device in an example in FIG. 12.

### 2. Model Size

The model had a length of 100 mm and a thickness equal to a total thickness of members in the sectional structure in FIG. 12, and a mesh was two-dimensionally created in thickness and length.

### 3. Bending Method

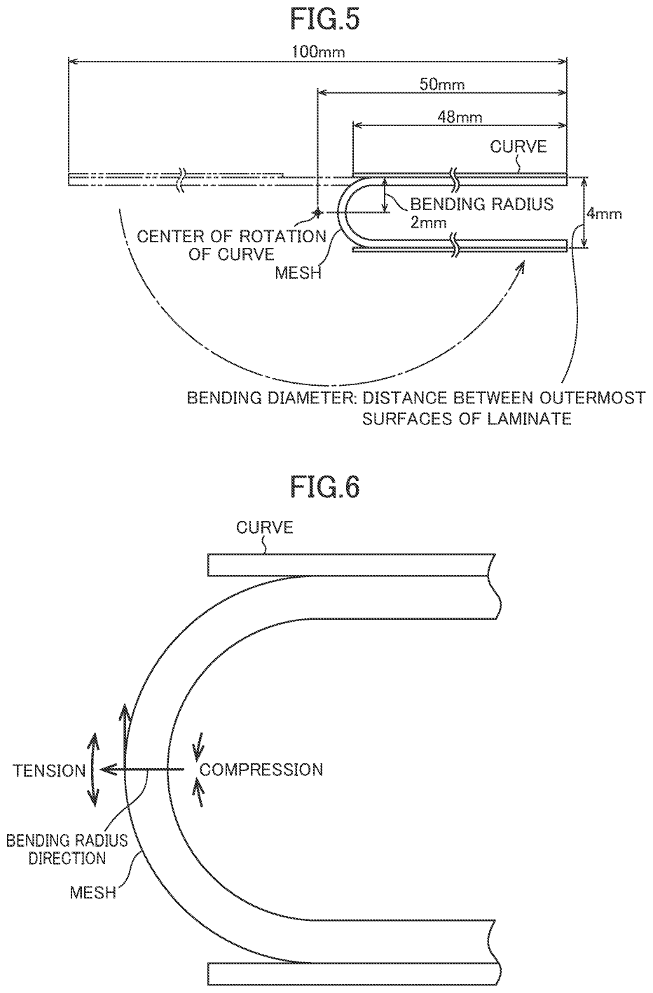

As shown in FIG. 5, curves having a length of 48 mm were set on opposite ends, ends of 10 mm of the mesh were fixed to the curves (rigid model), and the left curve was rotated by 180° to fold the mesh with its outermost surface outside. A bending diameter was 4 mm, which was a distance between outermost surfaces facing parallel to each other of the mesh with the left curve being rotated by 180°.

### 4. Input of Physical Values of Each Layer

For the window film, the polarizer protective film, the polarizer, the transparent resin substrate of the touch sensor member, the alternate transparent resin substrate of the panel member, and the protective member, strain and stress in strain-stress curve data of a tensile test for each member were converted into true strain (ln(strain+1) and true stress (stress(strain+1)), and input to a table with the type being set to signed_eq_mechanical_Strain. The type of the material property of a relevant part of the mesh was set to subelastic, and a stress-strain curve of the relevant material was selected from the table.

For an adhesive layer, first, the strain-stress curve data of the tensile test was subjected to fitting by the Mooney-Rivlin expression below to calculate coefficients C10, C01, C11. Then, the type of the material property of the relevant part of the mesh was set to Mooney, and the calculated coefficients C10, C01, C11 were input.

$$f = 2 ( γ - \frac{1}{{γ}^{2}} ) [ ( {C}_{10} + \frac{{C}_{01}}{γ} ) + 3 {C}_{11} ( γ - 1 ) ( 1 + {γ}^{- 1} ) ( 1 - {γ}^{- 1} ) ] \qquad [ Expression 1 ]$$

where γ=ε+1, f is nominal stress, and c is nominal strain.

For the retardation film, the type of the material property of the relevant part of the mesh was set to isotropic elastoplastic, and a difference between strain-test force curve data, obtained in the tensile test, of the laminate of the retardation film, polarizer, and polarizer protective film as the optical film member and strain-test force curve data, obtained in the tensile test, of the laminate of the polarizer and polarizer protective film was calculated to obtain a value of a curve corresponding to a strain-test force curve of the retardation film, the value of the curve divided by a sectional area (widthxthickness) of the retardation film was plotted as a curve corresponding to a strain-stress curve of the retardation film, and a slope of the curve within a range of strain of 0.05% to 0.25% was calculated and input as a modulus of the retardation film.

Also for the ITO layer, alternate ITO layer, and hard coat layer, the type of the material property of the relevant part of the mesh was similarly set to isotropic elastoplastic, a difference between strain-test force curve data, obtained in the tensile test, of the transparent resin substrate with the ITO layer as the touch sensor member and strain-test force curve data of the transparent resin substrate of the touch sensor member, a difference between strain-test force curve data, obtained in the tensile test, of the alternate transparent resin substrate with the alternate ITO layer as the panel member and strain-test force curve data of the alternate transparent resin substrate of the panel member, and a difference between strain-test force curve data, obtained in the tensile test, of the window film with the hard coat layer and strain-test force curve data of the window film were calculated, and moduli calculated based on the differences were input.

### <Simulation Results>

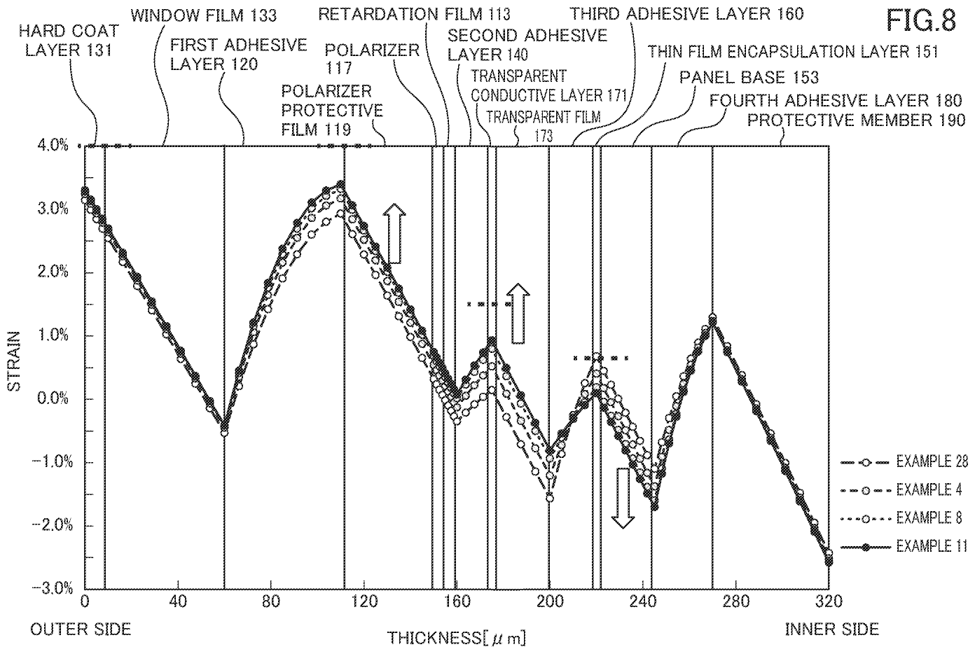

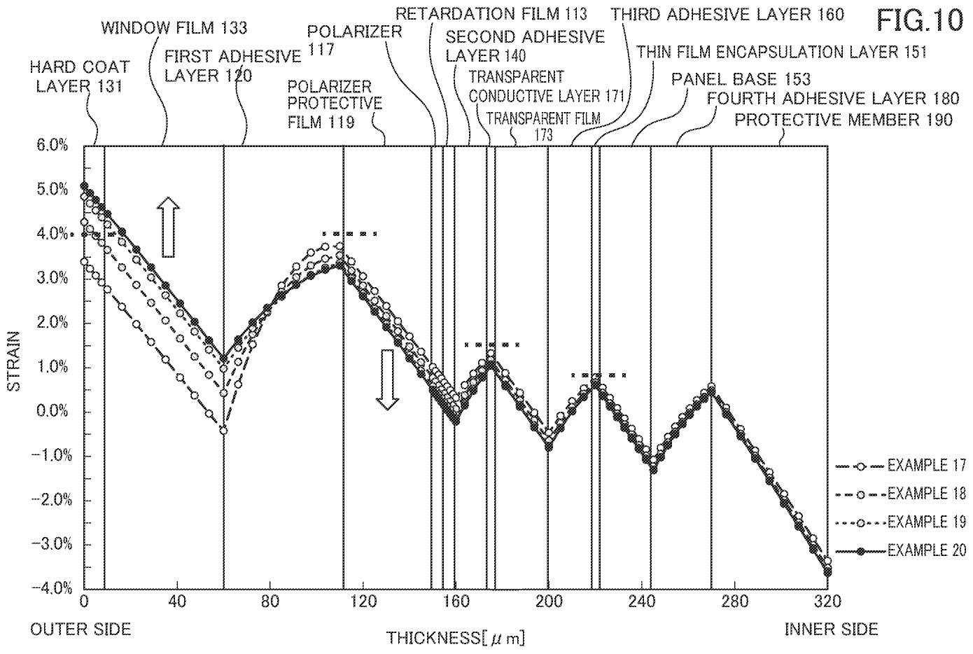

For the members in the examples and comparative examples, strains in bent parts in a direction perpendicular to a bending radius direction (Elastic Strain in Preferred Sys) (see FIG. 6) were calculated. FIGS. 8 to 11 show distributions, in a laminating direction, of strains in bent parts in a direction perpendicular to a bending radius direction calculated in Comparative Example 1 and Examples 9 to 11, Examples 28, 4, 8, and 11, Examples 8 and 14 to 16, and Examples 17 to 20, respectively.

Also, for the hard coat layer, polarizer protective film, ITO layer, and thin film encapsulation layer alternate ITO layer in each of the examples and comparative examples, Tables 2-1 to 2-3 show values of strains in outermost layers among the calculated strains in the bent parts in the direction perpendicular to the bending radius direction, and whether or not extension of each of the layers and films was lower than breaking extension.

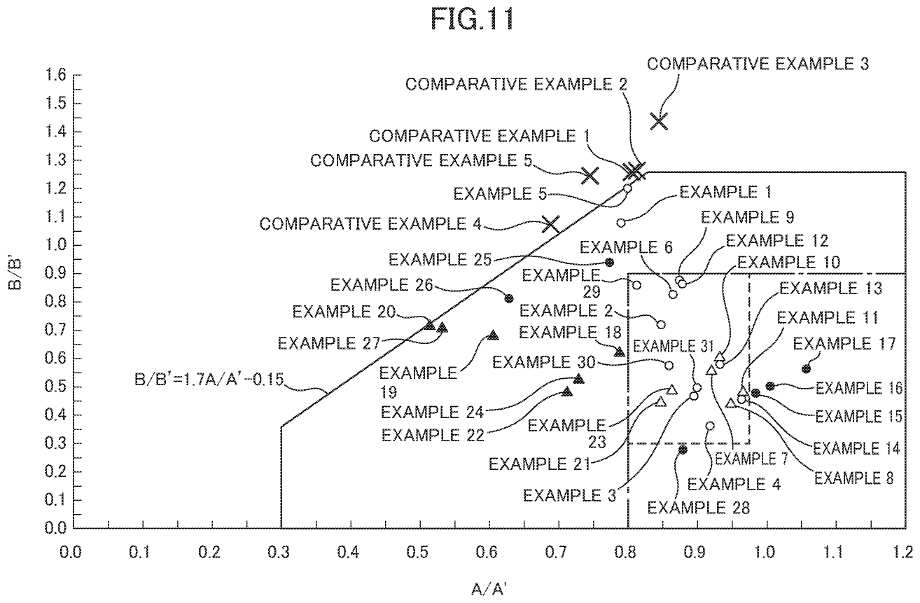

Also, for the examples and comparative examples, Tables 2-1 to 2-3 show values of A/A′, 1.7A/A′-0.15-B/B′, and B/B′ calculated from the calculated strains in the bent parts in the direction perpendicular to the bending radius direction. FIG. 11 shows a relationship between A/A′ and B/B.

### (Evaluation of Occurrence of Cracking)

For the samples of the dummy multilayer structure obtained in Examples 4, 8, 11, 14 to 18, 20, 24 to 26, and Comparative Examples 1, 2, and 4, it was checked whether or not cracking occurred in the hard coat layer, polarizer protective film, ITO layer, and thin film encapsulation layer alternate ITO layer in folding.

Specifically, as shown in FIG. 12, the multilayer structure was folded 180°, the folded multilayer structure was pressed from outside by glass plates. Further, a plate of 4 mm was inserted between the glass plates to hold a bent state such that a distance of 4 mm was kept between outermost surfaces facing parallel to each other of the multilayer structure. Cracking of the layers and the films were evaluated. Similarly to the simulation model, the bending diameter was 4 mm equal to the distance between the outermost surfaces facing parallel to each other of the multilayer structure with the multilayer structure being folded at an angle of 180°.

For the ITO layer and thin film encapsulation layer alternate ITO layer, occurrence of cracking was evaluated based on whether or not a resistance value of the ITO layer increased after bending. A conductive tape (strip terminal) was attached to the surface of the ITO layer such that resistance could be measured from outside the multilayer structure, and the resistance value was measured by a tester. The ITO layer having sheet resistance of 50 Ω/square was used, and the resistance value between strip terminals before bending was about 165 n. For the resistance value in the bent state 1.1 times or more of the resistance value before bending, cracking was evaluated to occur.

For the hard coat layer and polarizer protective film, occurrence of cracking was evaluated by microscopic observation or cross-sectional SEM observation after bending.

Tables 2-1 to 2-3 show cracking evaluation results of the examples and comparative examples.

### (Calculation of Breaking Extension)

Breaking extension of the polarizer protective film was calculated as described below. First, a bending test similar to that used in the evaluation of occurrence of cracking described above was performed with varying bending diameter, and a bending diameter with which cracking occurred was checked. Then, simulation similar to that described above was performed using the bending diameter with which cracking occurred was used as a bending diameter and using a single layer of the polarizer protective film as a model, and strain in a bent part in a direction perpendicular to a bending radius was calculated and taken as breaking extension.

For breaking extension of the hard coat layer, ITO layer, and alternate ITO layer, breaking extensions of the window film on which the hard coat layer was laminated, the transparent resin substrate, and the alternate transparent resin substrate were calculated by the calculation method similar to that of the breaking extension of the polarizer protective film and taken as respective breaking extensions.

Tables 2-1 to 2-3 show the calculated breaking extensions of the hard coat layer, polarizer protective film, ITO layer, and alternate ITO layer in the examples and comparative examples.

TABLE 2-1

| STRUCTURE | | EXAMPLE 1 | EXAMPLE 2 | EXAMPLE 3 | EXAMPLE 4 | EXAMPLE 5 | EXAMPLE 6 |
|---|---|---|---|---|---|---|---|
| WINDOW | TYPE OF WINDOW | 1 | 1 | 1 | 1 | 1 | 1 |
| MEMBER | FILM | | | | | | |
| FIRST | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | THICKNESS [μm] | 50 | 50 | 50 | 50 | 50 | 50 |
| SECOND | TYPE | 1 | 2 | 3 | 4 | 1 | 2 |
| ADHESIVE | G′ (25° C.) [Mpa] | 0.03 | 0.080 | 0.120 | 0.270 | 0.030 | 0.080 |
| LAYER | | | | | | | |
| THIRD | TYPE | 2 | 2 | 2 | 2 | 3 | 3 |
| ADHESIVE | G′ (25° C.) [Mpa] | 0.080 | 0.080 | 0.080 | 0.080 | 0.120 | 0.120 |
| LAYER | | | | | | | |
| FOURTH | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | | | | | | | |
| A/A′ | | 0.790 | 0.847 | 0.895 | 0.918 | 0.799 | 0.865 |
| 1.7A/A′-0.15-B/B′ | | 0.114 | 0.571 | 0.904 | 1.048 | 0.008 | 0.494 |
| B/B′ | | 1.078 | 0.719 | 0.467 | 0.362 | 1.200 | 0.825 |
| HARD | EXTENSION [%] | 3.08 | 3.19 | 3.23 | 3.24 | 3.10 | 3.22 |
| COAT | (BREAK: 4.00) | | | | | | |
| LAYER | LOWER THAN | YES | YES | YES | YES | YES | YES |
| | BREAKING | | | | | | |
| | EXTENSION? | | | | | | |
| POLARIZER | EXTENSION [%] | 2.53 | 2.86 | 3.08 | 3.17 | 2.59 | 2.95 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 1.18 | 0.86 | 0.62 | 0.52 | 1.47 | 1.14 |
| | (BREAK: 1.50) | | | | | | |
| | LOWER THAN | YES | YES | YES | YES | YES | YES |
| | BREAKING | | | | | | |
| | EXTENSION? | | | | | | |
| ALTERNATE | EXTENSION [%] | 0.57 | 0.47 | 0.42 | 0.41 | 0.41 | 0.28 |
| ITO LAYER | (BREAK: 0.65) | | | | | | |
| | LOWER THAN | YES | YES | YES | YES | YES | YES |
| | BREAKING | | | | | | |
| | EXTENSION? | | | | | | |

| | |
|---|---|
| OCCURRENCE OF CRACKING | NONE |

| STRUCTURE | | EXAMPLE 7 | EXAMPLE 8 | EXAMPLE 9 | EXAMPLE 10 | EXAMPLE 11 | EXAMPLE 12 |
|---|---|---|---|---|---|---|---|
| WINDOW | TYPE OF WINDOW | 1 | 1 | 1 | 1 | 1 | 1 |
| MEMBER | FILM | | | | | | |
| FIRST | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | THICKNESS [μm] | 50 | 50 | 50 | 50 | 50 | 50 |
| SECOND | TYPE | 3 | 4 | 2 | 3 | 4 | 2 |
| ADHESIVE | G′ (25° C.) [Mpa] | 0.120 | 0.270 | 0.080 | 0.120 | 0.270 | 0.080 |
| LAYER | | | | | | | |
| THIRD | TYPE | 3 | 3 | 4 | 4 | 4 | 3 |
| ADHESIVE | G′ (25° C.) [Mpa] | 0.120 | 0.120 | 0.270 | 0.270 | 0.270 | 0.120 |
| LAYER | | | | | | | |
| FOURTH | TYPE | 1 | 1 | 1 | 1 | 1 | 2 |
| ADHESIVE | G′ (25° C.) [Mpa] | 0.030 | 0.030 | 0.030 | 0.030 | 0.030 | 0.080 |
| LAYER | | | | | | | |
| A/A′ | | 0.920 | 0.948 | 0.874 | 0.932 | 0.966 | 0.878 |
| 1.7A/A′-0.15-B/B′ | | 0.859 | 1.023 | 0.459 | 0.831 | 1.011 | 0.479 |
| B/B′ | | 0.555 | 0.438 | 0.876 | 0.603 | 0.481 | 0.863 |
| HARD | EXTENSION [%] | 3.26 | 3.28 | 3.23 | 3.28 | 3.30 | 3.28 |
| COAT | (BREAK: 4.00) | | | | | | |
| LAYER | LOWER THAN | YES | YES | YES | YES | YES | YES |
| | BREAKING | | | | | | |
| | EXTENSION? | | | | | | |
| POLARIZER | EXTENSION [%] | 3.21 | 3.32 | 2.99 | 3.26 | 3.40 | 3.06 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 0.91 | 0.80 | 1.27 | 1.03 | 0.93 | 1.31 |
| | (BREAK: 1.50) | | | | | | |
| | LOWER THAN | YES | YES | YES | YES | YES | YES |
| | BREAKING | | | | | | |
| | EXTENSION? | | | | | | |
| ALTERNATE | EXTENSION [%] | 0.21 | 0.19 | 0.21 | 0.12 | 0.10 | 0.57 |
| ITO LAYER | (BREAK: 0.65) | | | | | | |
| | LOWER THAN | YES | YES | YES | YES | YES | YES |
| | BREAKING | | | | | | |
| | EXTENSION? | | | | | | |

| | | |
|---|---|---|
| OCCURRENCE OF CRACKING | NONE | NONE |

TABLE 2-2

| STRUCTURE | | EXAMPLE 13 | EXAMPLE 14 | EXAMPLE 15 | EXAMPLE 16 | EXAMPLE 17 | EXAMPLE 18 |
|---|---|---|---|---|---|---|---|
| WINDOW | TYPE OF WINDOW | 1 | 1 | 1 | 1 | 1 | 1 |
| MEMBER | FILM | | | | | | |
| FIRST | TYPE | 1 | 1 | 1 | 1 | 1 | 2 |
| ADHESIVE | G′ (25° C.) [Mpa] | 0.030 | 0.030 | 0.030 | 0.030 | 0.030 | 0.080 |
| LAYER | THICKNESS [μm] | 50 | 50 | 50 | 50 | 50 | 50 |
| SECOND | TYPE | 3 | 4 | 4 | 4 | 4 | 4 |
| ADHESIVE | G′ (25° C.) [Mpa] | 0.120 | 0.270 | 0.270 | 0.270 | 0.270 | 0.270 |
| LAYER | | | | | | | |
| THIRD | TYPE | 3 | 3 | 3 | 3 | 4 | 4 |
| ADHESIVE | G′ (25° C.) [Mpa] | 0.120 | 0.120 | 0.120 | 0.120 | 0.270 | 0.270 |
| LAYER | | | | | | | |
| FOURTH | TYPE | 2 | 2 | 3 | 4 | 4 | 4 |
| ADHESIVE | G′ (25° C.) [Mpa] | 0.080 | 0.080 | 0.120 | 0.270 | 0.270 | 0.270 |
| LAYER | | | | | | | |
| A/A′ | | 0.932 | 0.963 | 0.984 | 1.005 | 1.057 | 0.787 |
| 1.7A/A′-0.15-B/B′ | | 0.855 | 1.032 | 1.045 | 1.056 | 1.084 | 0.568 |
| B/B′ | | 0.579 | 0.455 | 0.478 | 0.502 | 0.563 | 0.620 |
| HARD | EXTENSION [%] | 3.33 | 3.35 | 3.39 | 3.43 | 3.39 | 4.28 |
| COAT | (BREAK: 4.00) | | | | | | |
| LAYER | LOWER THAN | YES | YES | YES | YES | YES | NO |
| | BREAKING | | | | | | |
| | EXTENSION? | | | | | | |
| POLARIZER | EXTENSION [%] | 3.32 | 3.45 | 3.55 | 3.62 | 3.74 | 3.53 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 1.06 | 0.96 | 1.07 | 1.14 | 1.33 | 1.17 |
| | (BREAK: 1.50) | | | | | | |
| | LOWER THAN | YES | YES | YES | YES | YES | YES |
| | BREAKING | | | | | | |
| | EXTENSION? | | | | | | |
| ALTERNATE | EXTENSION [%] | 0.50 | 0.48 | 0.73 | 0.88 | 0.78 | 0.67 |
| ITO LAYER | (BREAK: 0.65) | | | | | | |
| | LOWER THAN | YES | YES | NO | NO | NO | NO |
| | BREAKING | | | | | | |
| | EXTENSION? | | | | | | |

| | | | | | |
|---|---|---|---|---|---|
| OCCURRENCE OF CRACKING | NONE | CRACKING | CRACKING | CRACKING | CRACKING IN |
| | | ONLY IN | ONLY IN | ONLY IN | HARD COAT |
| | | ALTERNATE | ALTERNATE | ALTERNATE | LAYER AND |
| | | ITO LAYER | ITO LAYER | ITO LAYER | ALTERNATE |
| | | | | | ITO LAYER |

| STRUCTURE | | EXAMPLE 19 | EXAMPLE 20 | EXAMPLE 21 | EXAMPLE 22 | EXAMPLE 23 | EXAMPLE 24 |
|---|---|---|---|---|---|---|---|
| WINDOW | TYPE OF WINDOW | 1 | 1 | 1 | 1 | 1 | 1 |
| MEMBER | FILM | | | | | | |
| FIRST | TYPE | 3 | 4 | 1 | 2 | 1 | 2 |
| ADHESIVE | G′ (25° C.) [Mpa] | 0.120 | 0.270 | 0.030 | 0.080 | 0.030 | 0.080 |
| LAYER | THICKNESS [μm] | 50 | 50 | 25 | 50 | 25 | 50 |
| SECOND | TYPE | 4 | 4 | 4 | 4 | 4 | 4 |
| ADHESIVE | G′ (25° C.) [Mpa] | 0.270 | 0.270 | 0.270 | 0.270 | 0.270 | 0.270 |
| LAYER | | | | | | | |
| THIRD | TYPE | 4 | 4 | 3 | 3 | 4 | 4 |
| ADHESIVE | G′ (25° C.) [Mpa] | 0.270 | 0.270 | 0.120 | 0.120 | 0.270 | 0.270 |
| LAYER | | | | | | | |
| FOURTH | TYPE | 4 | 4 | 1 | 1 | 1 | 1 |
| ADHESIVE | G′ (25° C.) [Mpa] | 0.270 | 0.270 | 0.030 | 0.030 | 0.030 | 0.030 |
| LAYER | | | | | | | |
| A/A′ | | 0.605 | 0.532 | 0.847 | 0.712 | 0.863 | 0.728 |
| 1.7A/A′-0.15-B/B′ | | 0.200 | 0.047 | 0.847 | 0.578 | 0.831 | 0.562 |
| B/B′ | | 0.679 | 0.707 | 0.443 | 0.481 | 0.486 | 0.527 |
| HARD | EXTENSION [%] | 4.86 | 5.10 | 3.52 | 4.00 | 3.55 | 4.03 |
| COAT | (BREAK: 4.00) | | | | | | |
| LAYER | LOWER THAN | NO | NO | YES | NO | YES | NO |
| | BREAKING | | | | | | |
| | EXTENSION? | | | | | | |
| POLARIZER | EXTENSION [%] | 3.36 | 3.30 | 3.18 | 3.09 | 3.25 | 3.17 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 1.07 | 1.05 | 0.71 | 0.62 | 0.84 | 0.75 |
| | (BREAK: 1.50) | | | | | | |
| | LOWER THAN | YES | YES | YES | YES | YES | YES |
| | BREAKING | | | | | | |
| | EXTENSION? | | | | | | |
| ALTERNATE | EXTENSION [%] | 0.61 | 0.60 | 0.13 | 0.07 | 0.03 | −0.04 |
| ITO LAYER | (BREAK: 0.65) | | | | | | |
| | LOWER THAN | YES | YES | YES | YES | YES | YES |
| | BREAKING | | | | | | |
| | EXTENSION? | | | | | | |

| | | |
|---|---|---|
| OCCURRENCE OF CRACKING | CRACKING | CRACKING |
| | ONLY IN | ONLY IN |
| | HARD COAT | HARD COAT |
| | LAYER | LAYER |

TABLE 2-3

| STRUCTURE | | EXAMPLE 25 | EXAMPLE 26 | EXAMPLE 27 | EXAMPLE 28 | EXAMPLE 29 |
|---|---|---|---|---|---|---|
| WINDOW | TYPE OF WINDOW | 1 | 1 | 1 | 1 | 2 |
| MEMBER | FILM | | | | | |
| FIRST | TYPE | 1 | 2 | 3 | 1 | 1 |
| ADHESIVE | G′ (25° C.) [Mpa] | 0.030 | 0.080 | 0.120 | 0.030 | 0.030 |
| LAYER | THICKNESS [μm] | 50 | 50 | 50 | 50 | 50 |
| SECOND | TYPE | 1 | 2 | 3 | 4 | 2 |
| ADHESIVE | G′ (25° C.) [Mpa] | 0.030 | 0.080 | 0.120 | 0.270 | 0.080 |
| LAYER | | | | | | |
| THIRD | TYPE | 1 | 2 | 3 | 1 | 3 |
| ADHESIVE | G′ (25° C.) [Mpa] | 0.030 | 0.080 | 0.120 | 0.030 | 0.120 |
| LAYER | | | | | | |
| FOURTH | TYPE | 1 | 2 | 3 | 1 | 2 |
| ADHESIVE | G′ (25° C.) [Mpa] | 0.030 | 0.080 | 0.120 | 0.030 | 0.080 |
| LAYER | | | | | | |
| A/A′ | | 0.773 | 0.628 | 0.514 | 0.879 | 0.812 |
| 1.7A/A′-0.15-B/B′ | | 0.224 | 0.107 | 0.010 | 1.066 | 0.372 |
| B/B′ | | 0.939 | 0.811 | 0.714 | 0.287 | 0.858 |
| HARD | EXTENSION [%] | 3.02 | 3.91 | 4.66 | 3.14 | 3.64 |
| COAT | (BREAK: 4.00) | | | | | |
| LAYER | LOWER THAN | YES | YES | NO | YES | YES |
| | BREAKING | | | | | |
| | EXTENSION? | | | | | |
| POLARIZER | EXTENSION [%] | 2.41 | 2.70 | 2.98 | 2.93 | 3.15 |
| PROTECTIVE | (BREAK: 4.00) | | | | | |
| FILM | LOWER THAN | YES | YES | YES | YES | YES |
| | BREAKING | | | | | |
| | EXTENSION? | | | | | |
| ITO LAYER | EXTENSION [%] | 0.82 | 0.85 | 0.92 | 0.15 | 1.37 |
| | (BREAK: 1.50) | | | | | |
| | LOWER THAN | YES | YES | YES | YES | YES |
| | BREAKING | | | | | |
| | EXTENSION? | | | | | |
| ALTERNATE | EXTENSION [%] | 0.78 | 0.66 | 0.57 | 0.68 | 0.62 |
| ITO LAYER | (BREAK: 0.65) | | | | | |
| | LOWER THAN | NO | NO | YES | NO | YES |
| | BREAKING | | | | | |
| | EXTENSION? | | | | | |

| | | |
|---|---|---|
| OCCURRENCE OF CRACKING | CRACKING | CRACKING |
| | ONLY IN | ONLY IN |
| | ALTERNATE | ALTERNATE |
| | ITO LAYER | ITO LAYER |

| | | | | COMPARATIVE | COMPARATIVE |
|---|---|---|---|---|---|
| STRUCTURE | | EXAMPLE 30 | EXAMPLE 31 | EXAMPLE 1 | EXAMPLE 2 |
| WINDOW | TYPE OF WINDOW | 2 | 2 | 1 | 1 |
| MEMBER | FILM | | | | |
| FIRST | TYPE | 1 | 1 | 1 | 1 |
| ADHESIVE | G′ (25° C.) [Mpa] | 0.030 | 0.030 | 0.030 | 0.030 |
| LAYER | THICKNESS [μm] | 50 | 50 | 50 | 50 |
| SECOND | TYPE | 3 | 4 | 1 | 1 |
| ADHESIVE | G′ (25° C.) [Mpa] | 0.120 | 0.270 | 0.030 | 0.030 |
| LAYER | | | | | |
| THIRD | TYPE | 3 | 3 | 4 | 3 |
| ADHESIVE | G′ (25° C.) [Mpa] | 0.120 | 0.120 | 0.270 | 0.120 |
| LAYER | | | | | |
| FOURTH | TYPE | 2 | 2 | 1 | 2 |
| ADHESIVE | G′ (25° C.) [Mpa] | 0.080 | 0.080 | 0.030 | 0.080 |
| LAYER | | | | | |
| A/A′ | | 0.859 | 0.899 | 0.805 | 0.813 |
| 1.7A/A′-0.15-B/B′ | | 0.735 | 0.882 | −0.04 | −0.031 |
| B/B′ | | 0.575 | 0.497 | 1.258 | 1.262 |
| HARD | EXTENSION [%] | 3.69 | 3.71 | 3.11 | 3.16 |
| COAT | (BREAK: 4.00) | | | | |
| LAYER | LOWER THAN | YES | YES | YES | YES |
| | BREAKING | | | | |
| | EXTENSION? | | | | |
| POLARIZER | EXTENSION [%] | 3.40 | 3.52 | 2.62 | 2.68 |
| PROTECTIVE | (BREAK: 4.00) | | | | |
| FILM | LOWER THAN | YES | YES | YES | YES |
| | BREAKING | | | | |
| | EXTENSION? | | | | |
| ITO LAYER | EXTENSION [%] | 1.13 | 1.02 | 1.59 | 1.65 |
| | (BREAK: 1.50) | | | | |
| | LOWER THAN | YES | YES | NO | NO |
| | BREAKING | | | | |
| | EXTENSION? | | | | |
| ALTERNATE | EXTENSION [%] | 0.54 | 0.53 | 0.35 | 0.69 |
| ITO LAYER | (BREAK: 0.65) | | | | |
| | LOWER THAN | YES | YES | YES | NO |
| | BREAKING | | | | |
| | EXTENSION? | | | | |

| | | |
|---|---|---|
| OCCURRENCE OF CRACKING | CRACKING | CRACKING IN |
| | ONLY IN ITO | ITO LAYER |
| | LAYER | AND |
| | | ALTERNATE |
| | | ITO LAYER |

| | | COMPARATIVE | COMPARATIVE | COMPARATIVE |
|---|---|---|---|---|
| STRUCTURE | | EXAMPLE 3 | EXAMPLE 4 | EXAMPLE 5 |
| WINDOW | TYPE OF WINDOW | 1 | 1 | 2 |
| MEMBER | FILM | | | |
| FIRST | TYPE | 1 | 2 | 1 |
| ADHESIVE | G′ (25° C.) [Mpa] | 0.030 | 0.080 | 0.030 |
| LAYER | THICKNESS [μm] | 50 | 50 | 50 |
| SECOND | TYPE | 1 | 2 | 1 |
| ADHESIVE | G′ (25° C.) [Mpa] | 0.030 | 0.080 | 0.030 |
| LAYER | | | | |
| THIRD | TYPE | 4 | 4 | 3 |
| ADHESIVE | G′ (25° C.) [Mpa] | 0.270 | 0.270 | 0.120 |
| LAYER | | | | |
| FOURTH | TYPE | 4 | 4 | 2 |
| ADHESIVE | G′ (25° C.) [Mpa] | 0.270 | 0.270 | 0.080 |
| LAYER | | | | |
| A/A′ | | 0.844 | 0.688 | 0.745 |
| 1.7A/A′-0.15-B/B′ | | −0.152 | −0.054 | −0.128 |
| B/B′ | | 1.437 | 1.074 | 1.245 |
| HARD | EXTENSION [%] | 3.23 | 4.12 | 3.47 |
| COAT | (BREAK: 4.00) | | | |
| LAYER | LOWER THAN | YES | NO | YES |
| | BREAKING | | | |
| | EXTENSION? | | | |
| POLARIZER | EXTENSION [%] | 2.82 | 3.04 | 2.74 |
| PROTECTIVE | (BREAK: 4.00) | | | |
| FILM | LOWER THAN | YES | YES | YES |
| | BREAKING | | | |
| | EXTENSION? | | | |
| ITO LAYER | EXTENSION [%] | 2.04 | 1.55 | 1.69 |
| | (BREAK: 1.50) | | | |
| | LOWER THAN | NO | NO | NO |
| | BREAKING | | | |
| | EXTENSION? | | | |
| ALTERNATE | EXTENSION [%] | 1.01 | 0.78 | 0.73 |
| ITO LAYER | (BREAK: 0.65) | | | |
| | LOWER THAN | NO | NO | NO |
| | BREAKING | | | |
| | EXTENSION? | | | |

| | |
|---|---|
| OCCURRENCE OF CRACKING | CRACKING IN |
| | HARD COAT |
| | LAYER, ITO |
| | LAYER, AND |
| | ALTERNATE |
| | ITO LAYER |

TABLE 3

| | | COMPARATIVE | | | | COMPARATIVE | |
|---|---|---|---|---|---|---|---|
| STRUCTURE | | EXAMPLE 1 | EXAMPLE 9 | EXAMPLE 10 | EXAMPLE 11 | EXAMPLE 2 | EXAMPLE 12 |
| WINDOW | TYPE OF WINDOW | 1 | 1 | 1 | 1 | 1 | 1 |
| MEMBER | FILM | | | | | | |
| FIRST | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | THICKNESS [μm] | 50 | 50 | 50 | 50 | 50 | 50 |
| SECOND | TYPE | 1 | 2 | 3 | 4 | 1 | 2 |
| ADHESIVE | G′ (25° C.) [Mpa] | 0.030 | 0.080 | 0.120 | 0.270 | 0.030 | 0.080 |
| LAYER | | | | | | | |
| THIRD | TYPE | 4 | 4 | 4 | 4 | 3 | 3 |
| ADHESIVE | G′ (25° C.) [Mpa] | 0.270 | 0.270 | 0.270 | 0.270 | 0.120 | 0.120 |
| LAYER | | | | | | | |
| FOURTH | TYPE | 1 | 1 | 1 | 1 | 2 | 2 |
| ADHESIVE | G′ (25° C.) [Mpa] | 0.030 | 0.030 | 0.030 | 0.030 | 0.080 | 0.080 |
| LAYER | | | | | | | |
| A/A′ | | 0.805 | 0.874 | 0.932 | 0.966 | 0.813 | 0.878 |
| 1.7A/A′-0.15-B/B′ | | −0.04 | 0.459 | 0.831 | 1.011 | −0.031 | 0.479 |
| B/B′ | | 1.258 | 0.876 | 0.603 | 0.481 | 1.262 | 0.863 |
| HARD | EXTENSION [%] | 3.11 | 3.23 | 3.28 | 3.30 | 3.16 | 3.28 |
| COAT | (BREAK: 4.00) | | | | | | |
| LAYER | LOWER THAN | YES | YES | YES | YES | YES | YES |
| | BREAKING | | | | | | |
| | EXTENSION? | | | | | | |
| POLARIZER | EXTENSION [%] | 2.62 | 2.99 | 3.26 | 3.40 | 2.68 | 3.06 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 1.59 | 1.27 | 1.03 | 0.93 | 1.65 | 1.31 |
| | (BREAK: 1.50) | | | | | | |
| | LOWER THAN | NO | YES | YES | YES | NO | YES |
| | BREAKING | | | | | | |
| | EXTENSION? | | | | | | |
| ALTERNATE | EXTENSION [%] | 0.35 | 0.21 | 0.12 | 0.10 | 0.69 | 0.57 |
| ITO LAYER | (BREAK: 0.65) | | | | | | |
| | LOWER THAN | YES | YES | YES | YES | NO | YES |
| | BREAKING | | | | | | |
| | EXTENSION? | | | | | | |

| | | | |
|---|---|---|---|
| OCCURRENCE OF CRACKING | CRACKING | NONE | CRACKING IN |
| | ONLY IN ITO | | ITO LAYER |
| | LAYER | | AND |
| | | | ALTERNATE |
| | | | ITO LAYER |

| | | | | COMPARATIVE | | | |
|---|---|---|---|---|---|---|---|
| STRUCTURE | | EXAMPLE 13 | EXAMPLE 14 | EXAMPLE 5 | EXAMPLE 29 | EXAMPLE 30 | EXAMPLE 31 |
| WINDOW | TYPE OF WINDOW | 1 | 1 | 2 | 2 | 2 | 2 |
| MEMBER | FILM | | | | | | |
| FIRST | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | THICKNESS [μm] | 50 | 50 | 50 | 50 | 50 | 50 |
| SECOND | TYPE | 3 | 4 | 1 | 2 | 3 | 4 |
| ADHESIVE | G′ (25° C.) [Mpa] | 0.120 | 0.270 | 0.030 | 0.080 | 0.120 | 0.270 |
| LAYER | | | | | | | |
| THIRD | TYPE | 3 | 3 | 3 | 3 | 3 | 3 |
| ADHESIVE | G′ (25° C.) [Mpa] | 0.120 | 0.120 | 0.120 | 0.120 | 0.120 | 0.120 |
| LAYER | | | | | | | |
| FOURTH | TYPE | 2 | 2 | 2 | 2 | 2 | 2 |
| ADHESIVE | G′ (25° C.) [Mpa] | 0.080 | 0.080 | 0.080 | 0.080 | 0.080 | 0.080 |
| LAYER | | | | | | | |
| A/A′ | | 0.932 | 0.963 | 0.745 | 0.812 | 0.859 | 0.899 |
| 1.7A/A′-0.15-B/B′ | | 0.855 | 1.032 | −0.128 | 0.372 | 0.735 | 0.882 |
| B/B′ | | 0.579 | 0.455 | 1.245 | 0.858 | 0.575 | 0.497 |
| HARD | EXTENSION [%] | 3.33 | 3.35 | 3.47 | 3.64 | 3.69 | 3.71 |
| COAT | (BREAK: 4.00) | | | | | | |
| LAYER | LOWER THAN | YES | YES | YES | YES | YES | YES |
| | BREAKING | | | | | | |
| | EXTENSION? | | | | | | |
| POLARIZER | EXTENSION [%] | 3.32 | 3.45 | 2.74 | 3.15 | 3.40 | 3.52 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 1.06 | 0.96 | 1.69 | 1.37 | 1.13 | 1.02 |
| | (BREAK: 1.50) | | | | | | |
| | LOWER THAN | YES | YES | NO | YES | YES | YES |
| | BREAKING | | | | | | |
| | EXTENSION? | | | | | | |
| ALTERNATE | EXTENSION [%] | 0.50 | 0.48 | 0.73 | 0.62 | 0.54 | 0.53 |
| ITO LAYER | (BREAK: 0.65) | | | | | | |
| | LOWER THAN | YES | YES | NO | YES | YES | YES |
| | BREAKING | | | | | | |
| | EXTENSION? | | | | | | |

| | |
|---|---|
| OCCURRENCE OF CRACKING | NONE |

TABLE 4

| STRUCTURE | | EXAMPLE 28 | EXAMPLE 4 | EXAMPLE 8 | EXAMPLE 11 |
|---|---|---|---|---|---|
| WINDOW MEMBER | TYPE OF WINDOW FILM | 1 | 1 | 1 | 1 |
| FIRST ADHESIVE | TYPE | 1 | 1 | 1 | 1 |
| LAYER | G′ (25° C.) [Mpa] | 0.030 | 0.030 | 0.030 | 0.030 |
| | THICKNESS [μm] | 50 | 50 | 50 | 50 |
| SECOND | TYPE | 4 | 4 | 4 | 4 |
| ADHESIVE LAYER | G′ (25° C.) [Mpa] | 0.550 | 0.55 | 0.550 | 0.550 |
| THIRD ADHESIVE | TYPE | 1 | 2 | 3 | 4 |
| LAYER | G′ (25°) [Mpa] | 0.030 | 0.080 | 0.120 | 0.550 |
| FOURTH | TYPE | 1 | 1 | 1 | 1 |
| ADHESIVE LAYER | G′ (25°) [Mpa] | 0.030 | 0.030 | 0.030 | 0.030 |
| A/A′ | | 0.879 | 0.918 | 0.948 | 0.966 |
| 1.7A/A0.15-B/B′ | | 1.066 | 1.048 | 1.023 | 1.011 |
| B/B′ | | 0.287 | 0.362 | 0.438 | 0.481 |
| HARD COAT | EXTENSION %) (BREAK: 4.00) | 3.14 | 3.24 | 3.28 | 3.30 |
| LAYER | LOWER THAN BREAKING EXTENSION? | YES | YES | YES | YES |
| POLARIZER | EXTENSION % (BREAK: 4.00) | 2.93 | 3.17 | 3.32 | 3.40 |
| PROTECTIVE FILM | LOWER THAN BREAKING EXTENSION? | YES | YES | YES | YES |
| ITO LAYER | EXTENSION % (BREAK: 1.50) | 0.15 | 0.52 | 0.80 | 0.93 |
| | LOWER THAN BREAKING EXTENSION? | YES | YES | YES | YES |
| ALTERNATE | EXTENSION % (BREAK: 0.65) | 0.68 | 0.41 | 0.19 | 0.10 |
| ITO LAYER | LOWER THAN BREAKING EXTENSION? | NO | YES | YES | YES |

| | | | |
|---|---|---|---|
| OCCURRENCE OF CRACKING | NONE | NONE | NONE |

TABLE 5

| STRUCTURE | | EXAMPLE 8 | EXAMPLE 14 | EXAMPLE 15 | EXAMPLE 16 |
|---|---|---|---|---|---|
| WINDOW MEMBER | TYPE OF WINDOW FILM | 1 | 1 | 1 | 1 |
| FIRST ADHESIVE | TYPE | 1 | 1 | 1 | 1 |
| LAYER | G (25C) [Mpa] | 0.030 | 0.030 | 0.030 | 0.030 |
| | THICKNESS [um | 50 | 50 | 50 | 50 |
| SECOND | TYPE | 4 | 4 | 4 | 4 |
| ADHESIVE LAYER | G′ (25° C.) [Mpa] | 0.270 | 0.270 | 0.270 | 0.270 |
| THIRD ADHESIVE | TYPE | 3 | 3 | 3 | 3 |
| LAYER | G′ (25° C.) [Mpa] | 0.120 | 0.120 | 0.120 | 0.120 |
| FOURTH | TYPE | 1 | 2 | 3 | 4 |
| ADHESIVE LAYER | G′ (25°) [Mpa] | 0.03 | 0.080 | 0.120 | 0.270 |
| A/A′ | | 0.948 | 0.963 | 0.984 | 1.005 |
| 1.7A/A-0.15-B/B′ | | 1.023 | 1.032 | 1.045 | 1.056 |
| B/B′ | | 0.438 | 0.455 | 0.478 | 0.502 |
| HARD COAT | EXTENSION %) (BREAK: 4.00) | 3.28 | 3.35 | 3.39 | 3.43 |
| LAYER | LOWER THAN BREAKING EXTENSION? | YES | YES | YES | YES |
| POLARIZER | EXTENSION % (BREAK: 4.00) | 3.32 | 3.45 | 3.55 | 3.62 |
| PROTECTIVE FILM | LOWER THAN BREAKING EXTENSION? | YES | YES | YES | YES |
| ITO LAYER | EXTENSION % (BREAK: 1.50) | 0.80 | 0.96 | 1.07 | 1.14 |
| | LOWER THAN BREAKING EXTENSION? | YES | YES | YES | YES |
| ALTERNATE | EXTENSION [%\| (BREAK: 0.65) | 0.19 | 0.48 | 0.73 | 0.88 |
| ITO LAYER | LOWER THAN BREAKING EXTENSION? | YES | YES | NO | NO |

| | | | | |
|---|---|---|---|---|
| OCCURRENCE OF CRACKING | NONE | NONE | CRACKING | CRACKING |
| | | | ONLY IN | ONLY IN |
| | | | ALTERNATE | ALTERNATE |
| | | | ITO LAYER | ITO LAYER |

TABLE 6

| STRUCTURE | | EXAMPLE 8 | EXAMPLE 21 | EXAMPLE 22 | EXAMPLE 11 | EXAMPLE 23 | EXAMPLE 24 |
|---|---|---|---|---|---|---|---|
| WINDOW | TYPE OF WINDOW | 1 | 1 | 1 | 1 | 1 | 1 |
| MEMBER | FILM | | | | | | |
| FIRST | TYPE | 1 | 1 | 2 | 1 | 1 | 2 |
| ADHESIVE | G′ (25° C.) [Mpa] | 0.030 | 0.030 | 0.200 | 0.030 | 0.030 | 0.200 |
| LAYER | THICKNESS [μm] | 50 | 25 | 50 | 50 | 25 | 50 |
| SECOND | TYPE | 4 | 4 | 4 | 4 | 4 | 4 |
| ADHESIVE | G′ (25° C.) [Mpa] | 0.270 | 0.270 | 0.270 | 0.270 | 0.270 | 0.270 |
| LAYER | | | | | | | |
| THIRD | TYPE | 3 | 3 | 3 | 4 | 4 | 4 |
| ADHESIVE | G′ (25° C.) [Mpa] | 0.120 | 0.120 | 0.120 | 0.270 | 0.270 | 0.270 |
| LAYER | | | | | | | |
| FOURTH | TYPE | 1 | 1 | 1 | 1 | 1 | 1 |
| ADHESIVE | G′ (25° C.) [Mpa] | 0.030 | 0.030 | 0.030 | 0.030 | 0.030 | 0.030 |
| LAYER | | | | | | | |
| A/A′ | | 0.948 | 0.847 | 0.712 | 0.966 | 0.863 | 0.728 |
| 1.7A/A′-0.15-B/B′ | | 1.023 | 0.847 | 0.578 | 1.011 | 0.831 | 0.562 |
| B/B′ | | 0.438 | 0.443 | 0.481 | 0.481 | 0.486 | 0.527 |
| HARD | EXTENSION [%] | 3.28 | 3.52 | 4.00 | 3.30 | 3.55 | 4.03 |
| COAT | (BREAK: 4.00) | | | | | | |
| LAYER | LOWER THAN | YES | YES | NO | YES | YES | NO |
| | BREAKING | | | | | | |
| | EXTENSION? | | | | | | |
| POLARIZER | EXTENSION [%] | 3.32 | 3.18 | 3.09 | 3.40 | 3.25 | 3.17 |
| PROTECTIVE | (BREAK: 4.00) | | | | | | |
| FILM | LOWER THAN | YES | YES | YES | YES | YES | YES |
| | BREAKING | | | | | | |
| | EXTENSION? | | | | | | |
| ITO LAYER | EXTENSION [%] | 0.80 | 0.71 | 0.62 | 0.93 | 0.84 | 0.75 |
| | (BREAK: 1.50) | | | | | | |
| | LOWER THAN | YES | YES | YES | YES | YES | YES |
| | BREAKING | | | | | | |
| | EXTENSION? | | | | | | |
| ALTERNATE | EXTENSION [%] | 0.19 | 0.13 | 0.07 | 0.10 | 0.03 | −0.04 |
| ITO LAYER | (BREAK: 0.65) | | | | | | |
| | LOWER THAN | YES | YES | YES | YES | YES | YES |
| | BREAKING | | | | | | |
| | EXTENSION? | | | | | | |

| | | | |
|---|---|---|---|
| OCCURRENCE OF CRACKING | NONE | NONE | CRACKING |
| | | | ONLY IN |
| | | | HARD COAT |
| | | | LAYER |

### (Evaluations)

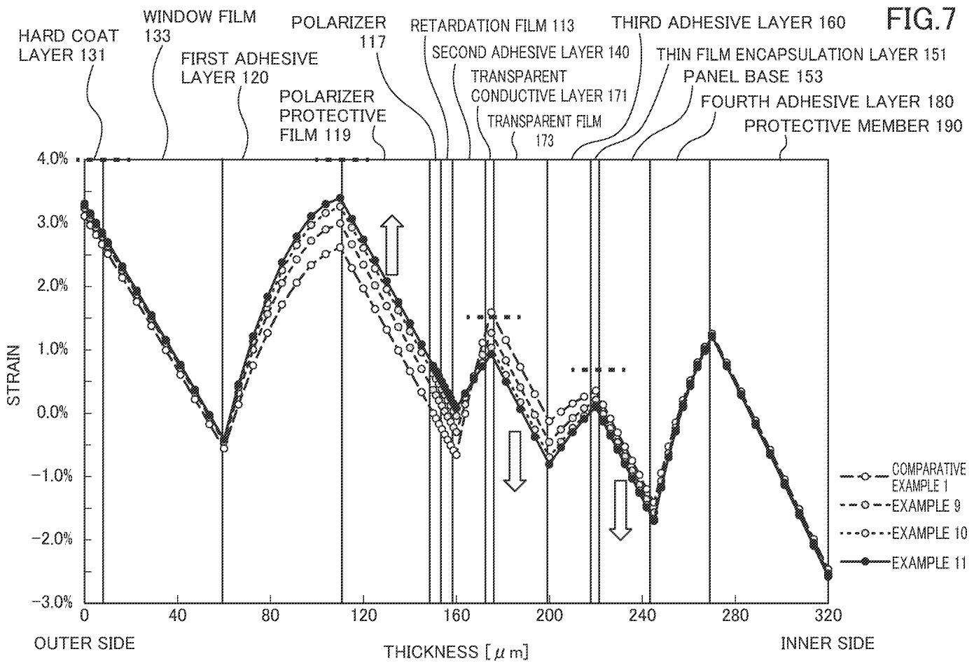

Tables 2-1 to 2-3 and FIGS. 7 to 10 show the following findings. Specifically in all of the examples and comparative examples, the values of the extensions of the hard coat layer that is the outer layer of the window member as the first member, the polarizer protective film that is the outer component of the circularly polarizing function film laminate as the second member, and the outer surface of the ITO layer that is the outer layer of the touch sensor member as the third member were positive, and tensile stress acted on the outer surfaces of the first member, the second member, and the third member.

Tables 2-1 to 2-3 and FIG. 11 show the following findings. Specifically, in the multilayer structures of Comparative Examples 1 to 5 in which the expressions: 0.3<A/A′<1.2 . . . (1), B/B′<1.7A/A′-0.15 . . . (2), and 0<B/B′<1.25 . . . (3) were not satisfied, the extension of the ITO layer when deformed by bending, which was calculated by the simulation, was higher than the breaking extension of 1.50% of the ITO layer. This showed that the ITO layer was broken. Also in the actually produced multilayer structures of Comparative Examples 1, 2, and 4, the ITO layer was cracked. To the contrary in the multilayer structures of Examples 1 to 31 in which Expressions (1) to (3) were satisfied, the extension of the ITO layer when deformed by bending, which was calculated by the simulation, was lower than the breaking extension of 1.50% of the ITO layer. This showed that ITO layer was not broken. Also in the actually produced multilayer structures of Examples 4, 8, 11, 14 to 18, 20, 24 to 26, no cracking was found in the ITO layer. As such, presence or absence of occurrence of cracking in the simulation results of the examples and comparative examples agreed well with those in the actually produced multilayer structures of the examples and comparative examples. Thus, it was found that determining the hardness of each of the first adhesive layer and the second adhesive layer as in the multilayer structures of Examples 1 to 31, for example, determining the shear modulus G′ or the thickness of each of the first adhesive layer and the second adhesive layer as in the multilayer structures of Examples 1 to 31, and also configuring the multilayer structures such that, for example, the values of A/A′ and B/B′ satisfy Expressions (1) to (3) might reduce the extension of the ITO layer when deformed by bending to lower than the breaking extension of the ITO layer, that is, might suppress break of the polarizer protective film.

In the multilayer structures of Examples 1 to 31, the extension of the polarizer protective film was also lower than the breaking extension (4.00%), and also in the actually produced multilayer structures of Examples 4, 8, 11, 14 to 18, 20, 24 to 26, no cracking was found in the polarizer protective film. Thus, determining the hardness of each of the first adhesive layer and the second adhesive layer as in the multilayer structures of Examples 1 to 31, for example, determining the shear modulus G′ or the thickness of each of the first adhesive layer and the second adhesive layer as in the multilayer structures of Examples 1 to 31, and also configuring the multilayer structures such that, for example, the values of A/A′ and B/B′ satisfy Expressions (1) to (3) might reduce the extension of the polarizer protective film when deformed by bending to lower than the breaking extension of the polarizer protective film, that is, might suppress break of the ITO layer.

In the multilayer structures of Examples 1 to 14, 19 to 24, 27, 29 to 31, the extension of the ITO layer calculated by the simulation was lower than the breaking extension, and the extension of the alternate ITO layer calculated by the simulation was also lower than the breaking extension (0.65%), and also in the actually produced multilayer structures of Examples 4, 8, 11, 14, 20, and 24, no cracking was found in the alternate ITO layer. As such, presence or absence of occurrence of cracking in the simulation results of the examples and comparative examples agreed well with those in the actually produced multilayer structures of the examples and comparative examples. Thus, it was found that determining the hardness of each of the first adhesive layer and the second adhesive layer as in the multilayer structures of Examples 1 to 14, 19 to 24, 27, and 29 to 31, for example, determining the shear modulus G′ or the thickness of each of the first adhesive layer and the second adhesive layer as in the multilayer structures of Examples 1 to 14, 19 to 24, 27, and 29 to 31 might also reduce the extension of the alternate ITO layer when deformed by bending to lower than the extension of the alternate ITO layer, that is, might suppress break of the alternate ITO layer.

In the multilayer structures of Examples 1 to 17, 21, 23, 25, 26, 28 to 31, the extension of the ITO layer calculated by the simulation was lower than the breaking extension, and the extension of the hard coat layer calculated by the simulation was also lower than the breaking extension (4.00%), and also in the actually produced multilayer structures of Examples 4, 8, 11, 14 to 17, 25, and 26, no cracking was found in the hard coat layer. As such, presence or absence of occurrence of cracking in the simulation results of the examples and comparative examples agreed well with those in the actually produced multilayer structures of the examples and comparative examples. Thus, it was found that determining the hardness of each of the first adhesive layer and the second adhesive layer as in the multilayer structures of Examples 1 to 17, 21, 23, 25, 26, and 28 to 31, for example, determining the shear modulus G′ or the thickness of each of the first adhesive layer and the second adhesive layer as in the multilayer structures of Examples 1 to 17, 21, 23, 25, 26, and 28 to 31, and also configuring the multilayer structures such that, for example, the values of A/A′ and B/B′ satisfy the expressions: 0.8<A/A′<1.2 and 0<B/B′<0.9 might also reduce the extension of the hard coat layer when deformed by bending to lower than the extension of the hard coat layer, that is, might suppress break of the hard coat layer.

In the multilayer structures of Examples 1 to 14, 21, 23, and 29 to 31, the extensions of all of the ITO layer, polarizer protective film, thin film encapsulation layer alternate ITO layer, and hard coat layer when deformed by bending, which were calculated by the simulation, were lower than the breaking extensions, and also in the actually produced multilayer structures of Examples 4, 8, 11, and 14, no cracking was found in all of the ITO layer, polarizer protective film, thin film encapsulation layer alternate ITO layer, and hard coat layer. As such, presence or absence of occurrence of cracking in the simulation results of the examples and comparative examples agreed well with those in the actually produced multilayer structures of the examples and comparative examples. Thus, it was found that determining the hardness of each of the first adhesive layer and the second adhesive layer as in the multilayer structures of Examples 1 to 14, 21, 23, and 29 to 31, for example, determining the shear modulus G′ or the thickness of each of the first adhesive layer and the second adhesive layer as in the multilayer structures of Examples 1 to 14, 21, 23, and 29 to 31, and also configuring the multilayer structures such that, for example, the values of A/A′ and B/B′ satisfy the expressions: 0.8<A/A′<0.975 and 0.3<B/B′<0.9 might reduce the extensions of all of the ITO layer, polarizer protective film, thin film encapsulation layer alternate ITO layer, and hard coat layer when deformed by bending to lower than the extensions of the layers and films, that is, might suppress break of the layers and films.

Table 3 shows Comparative Example 1 and Examples 9 to 11, Comparative Example 2 and Examples 12 to 14, and Comparative Example 5 and Examples 29 to 31 in Tables 2-1 to 2-3 being rearranged for ease of comparison. Tables 2-1 to 2-3, and 3 and FIG. 7 show the following findings.

The multilayer structures of Examples 1 to 4 had the same structure except the second adhesive layer. The shear modulus G′ of the second adhesive layer sequentially increased, while the extension of the ITO layer and the extension of the thin film encapsulation layer alternate ITO layer sequentially decreased.

The multilayer structures of Examples 5 to 8 had the same structure except the second adhesive layer, and the third adhesive layer was not the adhesive layer 1 in Examples 1 to 4 but the adhesive layer 2. The shear modulus G′ of the second adhesive layer sequentially increased, while the extension of the ITO layer and the extension of the thin film encapsulation layer alternate ITO layer sequentially decreased.

The multilayer structures of Comparative Example 1 and Examples 9 to 11 had the same structure except the second adhesive layer, and the third adhesive layer was not the adhesive layer 2 in Examples 1 to 4 or the adhesive layer 3 in Examples 5 to 8 but the adhesive layer 3. The shear modulus G′ of the second adhesive layer sequentially increased, while the extension of the ITO layer and the extension of the thin film encapsulation layer alternate ITO layer sequentially decreased.

The multilayer structures of Comparative Example 2 and Examples 12 to 14 had the same structure except the second adhesive layer, and the third adhesive layer was not the adhesive layer 1 in Examples 1 to 4, the adhesive layer 2 in Examples 5 to 8, and the adhesive layer 1 in Comparative Example 1 and Examples 9 to 11, but the adhesive layer 2. The shear modulus G′ of the second adhesive layer sequentially increased, while the extension of the ITO layer and the extension of the thin film encapsulation layer alternate ITO layer sequentially decreased.

The multilayer structures of Comparative Example 5 and Examples 29 to 31 had the same structure except the second adhesive layer, and the first adhesive layer, third adhesive layer, and fourth adhesive layer had the same structure as those in Comparative Example 2 and Example 12, and the window film of the window member was not the window film 1 in Examples 1 to 14 and Comparative Examples 1 and 2, but the window film 2. The shear modulus G′ of the second adhesive layer sequentially increased, while the extension of the ITO layer and the extension of the thin film encapsulation layer alternate ITO layer sequentially decreased.

From the above, it was found that increasing the shear modulus G′ of the second adhesive layer might reduce the extension of the ITO layer and the extension of the thin film encapsulation layer alternate ITO layer when deformed by bending, that is, might suppress break of the ITO layer and the thin film encapsulation layer alternate ITO layer.

In the method of manufacturing the multilayer structures of Examples A1 and A2, the multilayer structures of Comparative Example 1 and Example 11 had the same configuration and the multilayer structures of Comparative example 2 and Example 14 had the same configuration, except the second adhesive layers. Although the ITO layers in Comparative Examples 1 and 2 were expected to be broken by deformation by bending and was actually broken, changing the adhesive layers that form the second adhesive layers to those having higher shear moduli G′ in Examples 11 and 14 allowed manufacturing of the multilayer structures such that the extensions of the ITO layers were reduced to the values lower than the breaking extensions of the ITO layers.

Table 4 shows Examples 28, 4, 8, and 11 in Tables 2-1 to 2-3 being rearranged for ease of comparison. Tables 2-1 to 2-3, and 4 and FIG. 8 show the following findings.

The multilayer structures of Examples 28, 4, 8, and 11 had the same structure except the third adhesive layer. The shear modulus G′ of the third adhesive layer sequentially increased, and the extension of the ITO layer sequentially increased.

Thus, it was found that increasing the shear modulus G′ of the third adhesive layer might reduce the extension of the ITO layer when deformed by bending, that is, might suppress break of the ITO layer.

In the method of manufacturing the multilayer structure of Example B1, the multilayer structures of Comparative Example 1 and Example 25 had the same configuration except the third adhesive layers. Although the ITO layer in Comparative Example 1 was expected to be broken by deformation by bending and was actually broken, changing the adhesive layer that forms the third adhesive layer to that having a lower shear modulus G′ in Example 25 allowed manufacturing of the multilayer structure such that the extension of the ITO layer is reduced to the value lower than the breaking extension of the ITO layer.

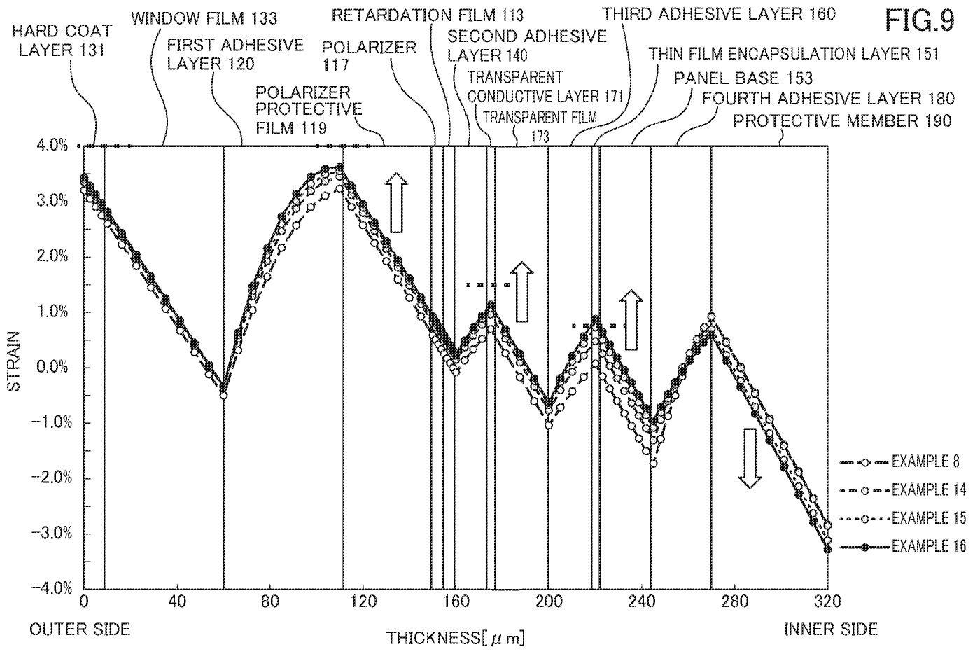

Table 5 shows Examples 8 and 14 to 16 in Tables 2-1 to 2-3 being rearranged for ease of comparison. Tables 2-1 to 2-3, 5 and FIG. 9 show the following findings.

The multilayer structures of Examples 8, 14 to 16 had the same structure except the fourth adhesive layer. The shear modulus G′ of the fourth adhesive layer sequentially increased, and the extension of the ITO layer and the extension of the thin film encapsulation layer alternate ITO layer sequentially increased.

Thus, it was found that reducing the shear modulus G′ of the fourth adhesive layer might reduce the extension of the ITO layer and the extension of the thin film encapsulation layer alternate ITO layer when deformed by bending, that is, might suppress break of the ITO layer and the thin film encapsulation layer alternate ITO.

In the method of manufacturing the multilayer structure of Example C1, the multilayer structures of Comparative Example 2 and Example 5 had the same configuration except the fourth adhesive layers. Although the ITO layer in Comparative Example 2 was expected to be broken by deformation by bending and was actually broken, the simulation expected that changing the adhesive layer that forms the fourth adhesive layer to that having a lower shear modulus G′ in Example 5 might reduce the extension of the ITO layer to the value lower than the breaking extension of the ITO layer, and it was highly probable that such a multilayer structure might be manufactured.

Table 6 shows Examples 8 and 21 to 22 and Examples 11 and 23 to 24 in Table 1 being rearranged for ease of comparison. Tables 2-1 to 2-3, and 6 and FIG. show the following findings.

The multilayer structures of Examples 17 to 20 had the same structure except the first adhesive layer. The shear modulus G′ of the first adhesive layer sequentially increased, and the extension of the hard coat layer sequentially increased.

The multilayer structures of Examples 8, 21, and 22 had the same structure except the first adhesive layer, and the third adhesive layer was not the adhesive layer 3 in Examples 17 to 20 but the adhesive layer 4, the fourth adhesive layer was not the adhesive layer 4 in Examples 17 to 20 but the adhesive layer 1. The shear modulus G″ of the first adhesive layer was the same in Examples 8 and 21, while the thickness of the first adhesive layer in Example 21 was smaller than that of the first adhesive layer in Example 8. Thus, the hardness of the first adhesive layer was higher in Example 21 than in Example 8. Also, as described above, the shear modulus G′ of the adhesive layer is a dominant factor in determining hardness of the adhesive layer. Since the shear modulus G′ in Example 22 was twice as high or higher than that in Example 21, the hardness of the first adhesive layer was higher in Example 22 than in Example 21. Thus, the hardness of the first adhesive layer sequentially increased, and the extension of the hard coat layer sequentially increased.

The multilayer structures of Examples 11, 23, and 24 had the same structure except the first adhesive layer, and the fourth adhesive layer was not the adhesive layer 3 in Examples 17 to 20 but the adhesive layer 4. The hardness of the first adhesive layer sequentially increased, and the extension of the hard coat layer sequentially increased.

From the above, it was found that reducing the hardness of the first adhesive layer might reduce the extension of the hard coat layer when deformed by bending, that is, might suppress break of the hard coat layer.

The arrows in the strain distribution charts in FIGS. 7 to 10 indicate whether strains in corresponding layers and films are shifted in a tensile direction or a compression direction when hardness of a corresponding adhesive layer is increased. The broken lines indicate breaking extensions of corresponding layers and films.

From FIGS. 7 to 10, it was found that if a certain adhesive layer was hardened in the multilayer structures of the examples and comparative examples including the plurality of layers and members laminated via the plurality of adhesive layers, strain in a layer or member laminated on an outer side of the adhesive layer was shifted in the tensile direction, and strain in a layer or member laminated on an inner side of the adhesive layer was shifted in the compression direction when the multilayer structure was folded.

For example, with reference to FIG. 7 for Comparative Example 1 and Examples 9 to 11, the shear modulus G′ of the second adhesive layer sequentially increased, that is, the hardness of the second adhesive layer increased. As the hardness of the second adhesive layer increased, the strain in the layer or member laminated on the outer side of the second adhesive layer was shifted in the tensile direction, and the strain in the layer or member laminated on the inner side of the second adhesive layer was shifted in the compression direction. The same applied to the sets of the examples and/or comparative examples in FIGS. 8 to 10.

The present invention has been described above for the particular embodiments with reference to the drawings, but various changes may be made in the present invention other than the illustrated and described configurations. Thus, the present invention is not limited to the illustrated and described configurations, but the scope of the present invention should be defined only in the appended claims and equivalent thereof.

### EXPLANATIONS OF LETTERS OR NUMERALS

100 multilayer structure
101 first structure
105 second structure
110 optical film member
111 polarizing film
113 retardation film
115 circularly polarizing function film laminate
117 polarizer
119 polarizer protective film
120 first adhesive layer
130 window member
131 hard coat layer
133 window film
140 second adhesive layer
150 panel member
151 thin film encapsulation layer
153 panel base
160 third adhesive layer
170 touch sensor member
171 transparent conductive layer
173 transparent film
180 fourth adhesive layer
190 protective member
901 organic EL display panel
912-1, 912-2 transparent conductive layer
915-1, 915-2 substrate film
916-1, 916-2 transparent conductive film
917 spacer
920 optical laminate
921 polarizer
922-1, 922-2 protective film
923 retardation film
930 touch panel

1. A multilayer structure comprising:
a first member;
a first adhesive layer;
a second member having one surface joined to one surface of the first member at least via the first adhesive layer;
a second adhesive layer; and
a first structure having one surface joined to the other surface of the second member at least via the second adhesive layer,
the multilayer structure being used to be deformed by bending with the first member outside,
wherein the first structure includes a third member on a surface in contact with the second adhesive layer,
the multilayer structure is configured such that when the multilayer structure is deformed by bending, tensile stress acts on at least each of outer surfaces of the first member, the second member, and the third member,
in the multilayer structure, the third member of the first structure includes, on a surface in contact with the second adhesive layer, a layer that has tensile breaking extension lower than that of each of the first member and the second member and is likely to be broken when deformed by bending, and
hardness of each of the first adhesive layer and the second adhesive layer is determined such that when the multilayer structure is deformed by bending, deformation by bending of the one surface of the first member, deformation by bending of the one surface of the second member, deformation by bending of the other surface of the second member, and deformation by bending of the one surface of the third member interact with one another via the first adhesive layer and the second adhesive layer, and that extension of the layer that is likely to be broken when deformed by bending is reduced to a value lower than the tensile breaking extension of the layer that is likely to be broken.

2. The multilayer structure according to claim 1, wherein the hardness of each of the first adhesive layer and the second adhesive layer is determined by a thickness and/or a shear modulus of each of the first adhesive layer and the second adhesive layer.

3. The multilayer structure according to claim 1, wherein the first member is a window member of a display device, the second member is a circularly polarizing function film laminate, the third member is a touch sensor member including a transparent conductive layer formed on a surface closer to the second adhesive layer, and a second structure is joined to a surface of the touch sensor member opposite to the second adhesive layer via a third adhesive layer.

4. The multilayer structure according to claim 3, wherein the second structure includes a panel member, and the panel member includes a thin film encapsulation layer on a surface closer to the third adhesive layer.

5. The multilayer structure according to claim 3, wherein the window member includes a hard coat layer on a surface opposite to the first adhesive layer.

6. The multilayer structure according to claim 4, wherein the circularly polarizing function film laminate is a laminate of a polarizing film and a retardation film, and
the polarizing film is a laminate of a polarizer and a polarizer protective film laminated on at least one surface of the polarizer.

7. The multilayer structure according to claim 6, wherein the polarizer protective film contains acrylic resin.

8. The multilayer structure according to claim 1, wherein the shear modulus of the second adhesive layer is higher than the shear modulus of the first adhesive layer.

9. The multilayer structure according to claim 4, wherein the second structure includes a fourth adhesive layer on a surface of the panel member opposite to the third adhesive layer, and a protective member laminated via the fourth adhesive layer.

10. The multilayer structure according to claim 9, wherein a shear modulus of the fourth adhesive layer is lower than the shear modulus of the second adhesive layer and lower than a shear modulus of the third adhesive layer.

11. A method of manufacturing a multilayer structure including a first member, a second member having one surface joined to one surface of the first member at least via a first adhesive layer, and a first structure having one surface joined to the other surface of the second member at least via a second adhesive layer, the multilayer structure being used to be deformed by bending with the first member outside,
wherein the first structure includes a third member on a surface in contact with the second adhesive layer,
the multilayer structure is configured such that when the multilayer structure is deformed by bending, tensile stress acts on at least each of outer surfaces of the first member, the second member, and the third member,
in the multilayer structure, the third member of the first structure includes, on a surface in contact with the second adhesive layer, a layer that has tensile breaking extension lower than that of each of the first member and the second member and is likely to be broken when deformed by bending, and
the method comprises:
determining whether the layer that is likely to be broken of the third member has been or is to be broken when deformed by bending, and when it is determined that the layer that is likely to be broken of the third member has been or is to be broken, increasing hardness of at least one of the first adhesive layer and the second adhesive layer, thereby manufacturing the multilayer structure such that extension of the layer that is likely to be broken of the third member when deformed by bending is reduced to a value lower than the tensile breaking extension of the layer that is likely to be broken.

12. The method of manufacturing a multilayer structure according to claim 11, wherein increasing the hardness of at least one of the first adhesive layer and the second adhesive layer is increasing a shear modulus of at least one of the first adhesive layer and the second adhesive layer and/or reducing a thickness of at least one of the first adhesive layer and the second adhesive layer.

13. The method of manufacturing a multilayer structure according to claim 11, wherein a second structure is joined to a surface of the third member opposite to the second adhesive layer via a third adhesive layer, and
the method comprises:
determining whether the layer that is likely to be broken of the third member has been or is to be broken when deformed by bending, and when it is determined that the layer that is likely to be broken of the third member has been or is to be broken, reducing hardness of the third adhesive layer, thereby manufacturing the multilayer structure such that extension of the layer that is likely to be broken of the third member when deformed by bending is reduced to a value lower than the tensile breaking extension of the layer that is likely to be broken.

14. The method of manufacturing a multilayer structure according to claim 13, wherein reducing the hardness of the third adhesive layer is reducing a shear modulus of the third adhesive layer and/or increasing a thickness of the third adhesive layer.

15. The method of manufacturing a multilayer structure according to claim 13, wherein the third member is a touch sensor member,
the layer that is likely to be broken is a transparent conductive layer formed on a surface of the touch sensor member closer to the second adhesive layer, the second structure includes a panel member, the panel member has a thin film encapsulation layer on a surface closer to the third adhesive layer,
the second structure further includes a fourth adhesive layer on a surface of the panel member opposite to the third adhesive layer, and a protective member laminated via the fourth adhesive layer, and
the method comprises:
determining whether the transparent conductive layer has been or is to be broken when deformed by bending, and
when it is determined that the transparent conductive layer has been or is to be broken, reducing hardness of at least one of the third adhesive layer and the fourth adhesive layer, thereby manufacturing the multilayer structure such that extension of the transparent conductive layer when deformed by bending is reduced to a value lower than the tensile breaking extension of the transparent conductive layer.

16. The method of manufacturing a multilayer structure according to claim 13, wherein reducing the hardness of at least one of the third adhesive layer and the fourth adhesive layer is reducing a shear modulus of at least one of the third adhesive layer and the fourth adhesive layer and/or increasing a thickness of at least one of the third adhesive layer and the fourth adhesive layer.
